(19) United States
(12) Patent Application Publication
(10) Pub. No.: US 2022/0360050 A1
(43) Pub. Date: Nov. 10, 2022

(54) SEMICONDUCTOR LIGHT EMITTING DEVICE

(71) Applicant: Panasonic Corporation, Osaka (JP)

(72) Inventor: Shinichiro NOZAKI, Osaka (JP)

(21) Appl. No.: 17/626,727

(22) PCT Filed: Jul. 21, 2020
(86) PCT No.: PCT/JP2020/028204

§ 371 Date: Jan. 12, 2022

Related U.S. Application Data
(60) Provisional application No. 62/877,162, filed on Jul. 22, 2019.

(51) Int. Cl. H01S 5/343; H01S 5/40

(52) U.S. Cl. CPC H01S 5/34333; H01S 5/4031

(57) ABSTRACT

A semiconductor light emitting device includes a substrate and a semiconductor multilayer stacked on the substrate. The semiconductor multilayer includes an n-side clad layer stacked above the substrate, an active layer stacked above the n-side clad layer, and a p-side clad layer stacked above the active layer. The semiconductor multilayer includes a first plane perpendicular to a stacking direction in which the semiconductor multilayer is stacked, and a lattice constant inside the first plane is an anisotropy constant.

### CROSS-REFERENCE OF RELATED APPLICATIONS

This application is the U.S. National Phase under 35 U.S.C. § 371 of International Patent Application No. PCT/JP2020/028204, filed on Jul. 21, 2020, which in turn claims the benefit of U.S. Provisional Application No. 62/877,162, filed on Jul. 22, 2019, the entire disclosures of which Applications are incorporated by reference herein.

### TECHNICAL FIELD

The present disclosure relates to semiconductor light emitting devices.

### BACKGROUND ART

Conventionally, laser light is used in processing applications, and thus high-power and high-efficient laser light sources are required. As the high-power and high-efficient laser light sources, semiconductor laser elements are utilized. As a high-power semiconductor laser element, a light emitting array element is known in which light emitting points serving as heat sources are dispersed and arranged in an array. A plurality of beams of laser light from the light emitting array element as described above are combined using an optical system into one beam of laser light to be used. In this case, when warpage occurs in the light emitting array element, intervals between the light emitting points are displaced, and thus the combination efficiency of the laser light from the light emitting array element and the optical system is lowered. The efficiency of the light source as a whole is lowered accordingly.

As a conventional technique for solving the problem as described above, for example, a light emitting array element disclosed in Patent Literature (PTL) 1 is known. The light emitting array element disclosed in PTL 1 will be described below with reference to FIG. 32. FIG. 32 is a perspective view schematically showing the configuration of light emitting array element 2001 disclosed in PTL 1. As shown in FIG. 32, light emitting array element 2001 includes substrate 2004 and semiconductor multilayers 2010. In light emitting array element 2001, dividing grooves are formed between light emitting points to extend partway through substrate 2004 from semiconductor multilayers 2010. In this way, in the light emitting array element disclosed in PTL 1, warpage attempts to be suppressed.

### CITATION LIST

### Patent Literature

[PTL 1] Japanese Unexamined Patent Application Publication No. 11-220204

### SUMMARY OF INVENTION

### Technical Problem

In a laser chip including a substrate and a semiconductor multilayer stacked on the substrate, in a free-standing state, between the semiconductor multilayer and the substrate, there is a difference in the lattice constant of a plane (for example, in GaN, a c-plane) perpendicular to the stacking direction of the semiconductor multilayer. In other words, a lattice mismatch occurs between the semiconductor multilayer and the substrate. In order to improve the warpage of a laser chip which has significant warpage resulting from a lattice mismatch, it is necessary to provide a wide groove in a semiconductor multilayer which is the source of distortion. When the laser chip is junction-down mounted on a mounting substrate or the like in a state where the wide groove is provided in the semiconductor multilayer as described above, a void is generated in the region of the groove, with the result that the heat dissipation property of the laser chip deteriorates. Hence, the light output property of the laser chip mounted is lowered.

The present disclosure solves the problems as described above, and an object thereof is to provide a semiconductor light emitting device which can reduce distortion resulting from a lattice mismatch.

### Solution to Problem

In order to solve the problems described above, a semiconductor light emitting device according to an aspect of the present disclosure is a semiconductor light emitting device that emits light in a direction of resonance, the semiconductor light emitting device includes: a substrate; and one or more semiconductor multilayers stacked on the substrate, each of the one or more semiconductor multilayers includes: an n-side clad layer stacked above the substrate; an active layer stacked above the n-side clad layer; and a p-side clad layer stacked above the active layer, each of the one or more semiconductor multilayers includes a first plane perpendicular to a stacking direction in which the one or more semiconductor multilayers are stacked, and a lattice constant inside the first plane is an anisotropy constant.

In order to solve the problems described above, a semiconductor light emitting device according to another aspect of the present disclosure includes a substrate; and one or more semiconductor multilayers stacked on the substrate, each of the one or more semiconductor multilayers includes: an n-side clad layer stacked above the substrate; an active layer that is stacked above the n-side clad layer and includes at least Al; and a p-side clad layer stacked above the active layer, each of the one or more semiconductor multilayers includes a first plane perpendicular to a stacking direction in which the one or more semiconductor multilayers are stacked, the first plane includes, inside the first plane, a first orientation and a third orientation that is tilted relative to the first orientation, the substrate includes a second plane perpendicular to the stacking direction, the second plane includes, inside the second plane, a second orientation parallel to the first orientation and a fourth orientation that is tilted relative to the second orientation and is parallel to the third orientation, a first lattice constant in the first orientation is equal to a second lattice constant in the second orientation, and a third lattice constant in the third orientation is less than a fourth lattice constant in the fourth orientation.

### Advantageous Effects of Invention

According to the present disclosure, it is possible to provide a semiconductor light emitting device which can reduce distortion resulting from a lattice mismatch.

### BRIEF DESCRIPTION OF DRAWINGS

FIG. 1 is a schematic top view of a semiconductor light emitting device according to embodiment 1.

FIG. 2 is a schematic cross-sectional view of the semiconductor light emitting device according to embodiment 1.

FIG. 3 is schematic views showing the states of the crystal structures of a substrate and a semiconductor multilayer in embodiment 1.

FIG. 4A is a diagram showing X-ray reciprocal lattice mapping of the semiconductor light emitting device according to embodiment 1 in the direction of resonance.

FIG. 4B is a diagram showing X-ray reciprocal lattice mapping of the semiconductor light emitting device according to embodiment 1 in the direction of tilt.

FIG. 5 is a graph showing the result of the measurement of X-ray diffraction (2 θ/w) in the semiconductor light emitting device according to embodiment 1.

FIG. 6 is a graph showing the result of the measurement of the amount of warpage of the semiconductor light emitting device according to embodiment 1.

FIG. 7A is a first graph showing the result of Raman spectrum measurements in the semiconductor light emitting device according to embodiment 1.

FIG. 7B is a second graph showing the result of Raman spectrum measurements in the semiconductor light emitting device according to embodiment 1.

FIG. 8A is a cross-sectional view showing a first step in a method of manufacturing the semiconductor light emitting device according to embodiment 1.

FIG. 8B is a cross-sectional view showing a second step in the method of manufacturing the semiconductor light emitting device according to embodiment 1.

FIG. 8C is a cross-sectional view showing a third step in the method of manufacturing the semiconductor light emitting device according to embodiment 1.

FIG. 8D is a cross-sectional view showing a fourth step in the method of manufacturing the semiconductor light emitting device according to embodiment 1.

FIG. 8E is a cross-sectional view showing a fifth step in the method of manufacturing the semiconductor light emitting device according to embodiment 1.

FIG. 9 is a schematic top view of a semiconductor light emitting device according to embodiment 2.

FIG. 10 is a schematic cross-sectional view of the semiconductor light emitting device according to embodiment 2.

FIG. 11 is a schematic top view of a semiconductor light emitting device according to embodiment 3.

FIG. 12 is a schematic cross-sectional view of the semiconductor light emitting device according to embodiment 3.

FIG. 13 is a schematic top view of a semiconductor light emitting device according to embodiment 4.

FIG. 14 is a schematic cross-sectional view of the semiconductor light emitting device according to embodiment 4.

FIG. 15A is a diagram schematically showing a relationship between the energy band structure of a semiconductor light emitting device of a conventional technique and the distortion of an active layer.

FIG. 15B is a diagram schematically showing a relationship between the energy band structure of the semiconductor light emitting device according to embodiment 4 and the distortion of an active layer.

FIG. 16 is a schematic top view of a semiconductor light emitting device according to embodiment 5.

FIG. 17 is a schematic cross-sectional view of the semiconductor light emitting device according to embodiment 5.

FIG. 18 is a schematic top view of a semiconductor light emitting device according to embodiment 6.

FIG. 19 is a schematic cross-sectional view of the semiconductor light emitting device according to embodiment 6.

FIG. 20 is a schematic top view of a semiconductor light emitting device according to embodiment 7.

FIG. 21 is a schematic cross-sectional view of the semiconductor light emitting device according to embodiment 7.

FIG. 22 is a schematic top view of a semiconductor light emitting device according to embodiment 8.

FIG. 23 is a schematic cross-sectional view of the semiconductor light emitting device according to embodiment 8.

FIG. 24 is a schematic top view showing a first example of the configuration of a p-side pad electrode in a semiconductor light emitting device according to embodiment 9.

FIG. 25 is a schematic top view showing a second example of the configuration of the p-side pad electrode in the semiconductor light emitting device according to embodiment 9.

FIG. 26 is a schematic top view showing a third example of the configuration of the p-side pad electrode in the semiconductor light emitting device according to embodiment 9.

FIG. 27 is a schematic bottom view showing a first example of the configuration of an n electrode in the semiconductor light emitting device according to embodiment 9.

FIG. 28 is a schematic bottom view showing a second example of the configuration of the n electrode in the semiconductor light emitting device according to embodiment 9.

FIG. 29 is a schematic bottom view showing a third example of the configuration of the n electrode in the semiconductor light emitting device according to embodiment 9.

FIG. 30 is a schematic top view of a semiconductor light emitting device according to embodiment 10.

FIG. 31 is a schematic cross-sectional view of the semiconductor light emitting device according to embodiment 10.

FIG. 32 is a perspective view showing the configuration of a light emitting array element disclosed in PTL 1.

### DESCRIPTION OF EMBODIMENTS

Embodiments of the present disclosure will be described below with reference to drawings. The embodiments described below show specific examples of the present disclosure. Hence, values, shapes, materials, constituent elements, the arrangements, positions, and connection forms of the constituent elements, and the like which are shown in the embodiments below are examples, and are not intended to limit the present disclosure.

The drawings each are schematic views, and are not exactly shown. Hence, in the drawings, scales and the like are not necessarily the same as each other. In the drawings, substantially the same configurations are identified with the same reference signs, and the repeated description thereof is omitted or simplified.

In the present specification, the terms “upward” and “downward” do not indicate an upward direction (vertically upward) and a downward direction (vertically downward) in absolute spatial recognition but are used as terms which are defined by a relative positional relationship based on the order of layers stacked in a multilayer configuration. The terms “upward” and “downward” are applied not only to a case where two constituent elements are spaced with another constituent element present between the two constituent elements but also to a case where two constituent elements are arranged in contact with each other.

### Embodiment 1

A semiconductor light emitting device according to embodiment 1 will be described.

### Configuration

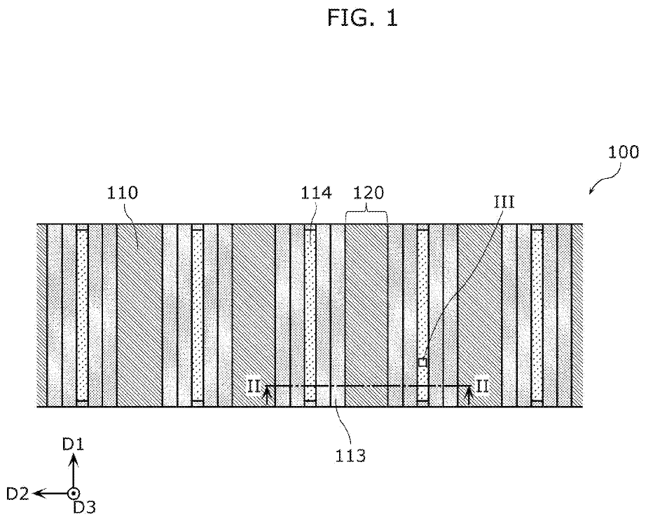

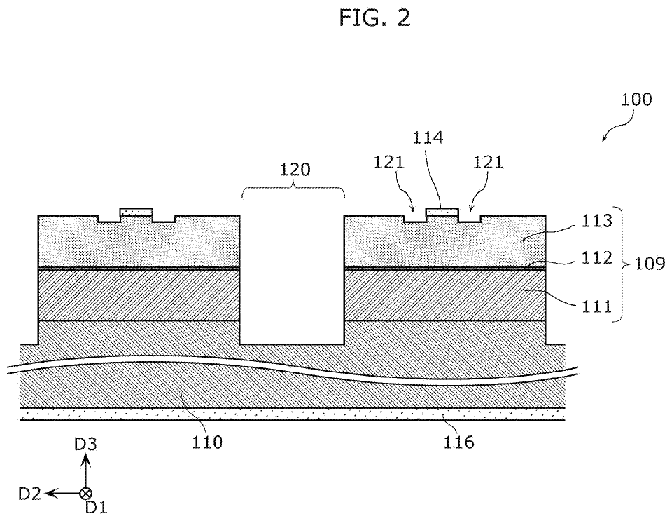

The configuration of semiconductor light emitting device 100 according to the present embodiment will first be described with reference to FIGS. 1 and 2. FIGS. 1 and 2 are respectively a schematic top view and a schematic cross-sectional view of semiconductor light emitting device 100 according to the present embodiment. FIG. 2 shows a cross section taken along line II-II in FIG. 1. In FIGS. 1 and 2 and parts of drawings described later, first direction D1, second direction D2, and third direction D3 which are perpendicular to each other are shown.

Semiconductor light emitting device 100 is a semiconductor device which emits light. In the present embodiment, semiconductor light emitting device 100 is a laser chip which emits laser light. The direction of emission of the light of semiconductor light emitting device 100 is a direction parallel to first direction D1 shown in FIGS. 1 and 2. In other words, the direction of resonance of the light (that is, the direction of a resonator) is a direction parallel to first direction D1 shown in FIGS. 1 and 2. The light (laser light) is mainly emitted from one of both end surfaces of semiconductor light emitting device 100 shown in FIG. 1 in first direction D1.

As shown in FIG. 2, semiconductor light emitting device 100 includes substrate 110 and semiconductor multilayers 109 stacked on substrate 110.

In the present embodiment, semiconductor light emitting device 100 further includes p electrodes 114 and n electrode 116.

Semiconductor multilayer 109 includes n-side clad layer 111 which is stacked above substrate 110, active layer 112 which is stacked above n-side clad layer 111, and p-side clad layer 113 which is stacked above active layer 112. In the present embodiment, semiconductor multilayer 109 includes a gallium nitride-based semiconductor. A stacking direction in which semiconductor multilayer 109 is stacked is a direction parallel to third direction D3 shown in FIGS. 1 and 2. In other words, the stacking direction is a direction perpendicular to the major surface of substrate 110 on which semiconductor multilayer 109 is stacked and is the direction of thickness of the layers of the semiconductor multilayer. In the present embodiment, semiconductor light emitting device 100 includes a plurality of semiconductor multilayers 109. A width of each of semiconductor multilayers 109 in the direction of resonance is less than a total of widths in a direction (second direction D2) perpendicular to the direction of resonance and the stacking direction.

Furthermore, as shown in FIGS. 1 and 2, a plurality of p electrodes 114 are provided on p-side clad layers 113. A current is injected between p electrodes 114 and n electrode 116 provided on the back surface (lower surface in FIG. 2) of substrate 110.

Both end surfaces of semiconductor multilayer 109 in first direction D1 form a resonator, and a region into which the current is injected with p electrode 114 is sandwiched between both the end surfaces. A direction perpendicular to both the end surfaces, that is, first direction D1 is defined as the direction of resonance of the light. As shown in FIG. 1, semiconductor light emitting device 100 may include one or more resonators which correspond to one or more p electrodes 114. Semiconductor light emitting device 100 may have a laser array structure which includes a plurality of resonators.

As shown in FIG. 2, in the regions of p-side clad layer 113 located on the sides (second direction D2) of p electrode 114, a pair of grooves 121 are provided which extend parallel to the direction of resonance (that is, first direction D1). In this way, in p-side clad layer 113 of semiconductor multilayer 109, a ridge for confining the light and the current can be formed.

In the present embodiment, semiconductor light emitting device 100 includes one or more groove regions 120 which are arranged above substrate 110 and which extend parallel to the direction of resonance. When semiconductor light emitting device 100 includes a plurality of semiconductor multilayers 109, between one semiconductor multilayer 109 and other semiconductor multilayers 109, one or more groove regions 120 deeper than grooves 121 for forming the ridges are formed. For the number of one or more groove regions 120, for example, a relationship may be satisfied in which a number obtained by subtracting 1 from the total number of semiconductor multilayers 109 is greater than the total number of groove regions 120. In other words, for the total number L (L is an integer greater than or equal to 2 or more) of semiconductor multilayers 109 and the total number M (M is an integer greater than or equal to 0) of groove regions 120, a relationship of L-1>M may be satisfied.

When semiconductor light emitting device 100 includes a plurality of resonators, between a certain resonator and resonators other than the certain resonator, at least one groove region 120 deeper than groove 121 for forming the ridge is provided.

Although the depth of groove region 120 is not particularly limited as long as groove region 120 is deeper than groove 121, groove region 120 may reach substrate 110. In this way, it is possible to reduce distortion resulting from a lattice mismatch between substrate 110 and semiconductor multilayer 109.

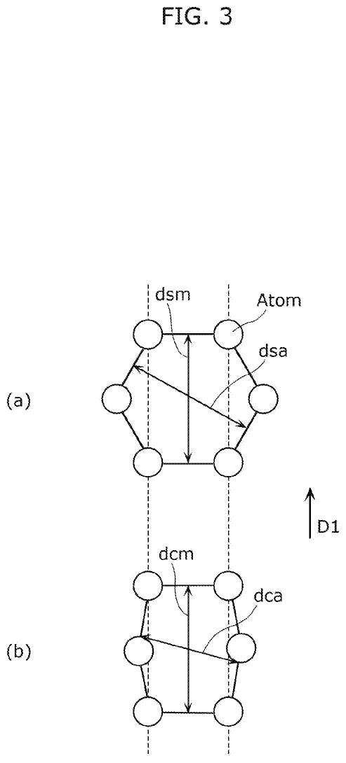

Here, the crystal structure of n-side clad layer 111 in the present embodiment will be described with reference to FIG. 3. FIG. 3 is schematic views showing the states of the crystal structures of substrate 110 and semiconductor multilayer 109 in the present embodiment. Schematic views (a) and (b) in FIG. 3 respectively show the crystal structures of cross sections of substrate 110 and n-side clad layer 111 in a region of square frame III in FIG. 1 perpendicular to the direction of resonance. Here, the cross section of n-side clad layer 111 perpendicular to the stacking direction is an example of a first plane perpendicular to the stacking direction included in semiconductor multilayer 109, and is also referred to as the first plane in the following description. The cross section of substrate 110 perpendicular to the stacking direction is an example of a second plane perpendicular to the stacking direction included in substrate 110, and is also referred to as the second plane in the following description.

Lattice constant dcm inside the first plane of n-side clad layer 111 shown in schematic view (b) in FIG. 3 in the direction of resonance is equal to lattice constant dsm inside the second plane of substrate 110 shown in schematic view (a) in the direction of resonance (first direction D1). A state where lattice constant dsm is equal to lattice constant dcm is not limited to a state where lattice constant dsm is completely identical to lattice constant dcm, and includes a state where they are substantially the same. For example, a state where a difference between lattice constant dsm and lattice constant dcm is less than or equal to 0.01% of lattice constant dsm or lattice constant dcm is also included in the state where lattice constant dsm is equal to lattice constant dcm.

Lattice constant dca inside the first plane of n-side clad layer 111 shown in schematic view (b) in FIG. 3 in a direction of tilt that is tiled relative to the direction of resonance is less than lattice constant dsa inside the second plane of substrate 110 shown in schematic view (a) in a direction of tilt.

In other words, for the lattice constants described above, a relationship represented by formulae (1) and (2) below is established.

dsm≈dcm (1)

dsa>dca (2)

Instead of the relationship represented by formulae (1) and (2) above, a relationship represented by formula (3) below may be established.

dsm-dcm<dsa-dca (3)

In the present embodiment, the stacking direction of semiconductor multilayer 109 is the direction of a c-axis in the crystal structure of substrate 110. Substrate 110 and semiconductor multilayer 109 in the present embodiment have a crystal structure of a hexagonal system. The direction of tilt is a crystal orientation which is determined by a crystal structure, and in the present embodiment, the direction of tilt is a direction which is tilted at 60 degrees or 120 degrees relative to the direction of resonance inside the first plane or inside the second plane.

The direction of tilt in the first plane and the direction of tilt in the second plane are parallel to each other. In other words, the direction of tilt in the first plane and the direction of tilt in the second plane are the same direction. Here, a state where the direction of tilt in the first plane and the direction of tilt in the second plane are parallel to each other includes not only a state where the direction of tilt in the first plane and the direction of tilt in the second plane are completely parallel to each other but also a state where they are substantially parallel. For example, a state where the direction of tilt in the first plane and the direction of tilt in the second plane are displaced from a completely parallel state by the degree of a change in the direction of tilt caused by the anisotropy of the lattice constant is also included in the state where the direction of tilt in the first plane and the direction of tilt in the second plane are parallel to each other.

The fact that although planes are equivalent from the point of view of crystal symmetry, the lattice constant is different depending on the plane orientation is defined as the lattice constant being an anisotropy constant. For example, the lattice constant inside the first plane of semiconductor multilayer 109 is an anisotropy constant.

A difference between lattice constant dsa in the second plane in the direction of tilt and lattice constant dca in the first plane in the direction of tilt is, for example, greater than or equal to 0.03% of lattice constant dsa or lattice constant dca. The difference between lattice constant dsa in the second plane in the direction of tilt and lattice constant dca in the first plane in the direction of tilt may be greater than or equal to 0.05% of lattice constant dsa or lattice constant dca. In this way, the anisotropy of the lattice constant in the first plane is more remarkable. The difference between lattice constant dsa in the second plane in the direction of tilt and lattice constant dca in the first plane in the direction of tilt may be less than or equal to 0.1% of lattice constant dsa or lattice constant dca.

In the present embodiment, substrate 110 may include gallium nitride (GaN). For example, substrate 110 may be a GaN single crystal substrate which is oriented to the c-axis. In other words, substrate 110 may include GaN, and the major surface (surface on which semiconductor multilayer 109 is stacked) of substrate 110 may be a c-plane. Substrate 110 may include silicon carbide (SiC) or sapphire. As substrate 110, a crystalline substrate having a lattice mismatch for semiconductor multilayer 109 may be used instead. The width (that is, the length of the resonator) of substrate 110 in the direction of resonance is, for example, 2 mm. The width (that is, the width in second direction D2) of substrate 110 perpendicular to the direction of resonance and the stacking direction is 10 mm. As described above, the depth of groove region 120 may reach substrate 110. For example, the depth of groove region 120 is 4 μm from the surface of semiconductor light emitting device 100 (that is, the upper surface of semiconductor multilayer 109). Although the width of groove region 120 (that is, the width in second direction D2) is not particularly limited, the width is, for example, 100 μm. The cross-sectional shape of groove region 120 may be concave in the cross section as shown in FIG. 2. In the present embodiment, the width of groove region 120 does not depend on the position in the direction of depth to be constant. In other words, the cross-sectional shape of groove region 120 in the present embodiment is a single-step shape (rectangular shape). The cross-sectional shape of groove region 120 may be such a tapered shape that as groove region 120 extends closer to n electrode 116 on the back surface of substrate 110 in the cross section as shown in FIG. 2, the width is decreased (that is, the width is decreased toward the end) or may be such a tapered shape that as groove region 120 extends closer to n electrode 116 on the back surface of substrate 110, the width is increased (that is, the width is increased toward the end). The cross-sectional shape of groove region 120 may be such a multistep shape that the width is stepwise changed in the cross section as shown in FIG. 2.

N-side clad layer 111 is stacked on substrate 110. In the present embodiment, the thickness of n-side clad layer 111 may be greater than or equal to 1 μm. For example, the thickness of n-side clad layer 111 may be 3 μm, and the composition thereof may be n-AlₓGa₁₋ₓN (0<x<1). N-side clad layer 111 may be doped with Si. For example, the concentration of Si may be 1×10¹⁷ cm⁻³.

Active layer 112 is stacked on n-side clad layer 111. Active layer 112 includes, for example, a gallium nitride-based material. In the present embodiment, active layer 112 is a quantum well active layer in which a well layer including InₓGa₁₋ₓN (0<x<1) and a barrier layer including AlₓIn_{y}GaN (0≤x,y) are alternately stacked. Active layer 112 includes, for example, two well layers. As long as active layer 112 is a quantum well active layer, the number of well layers is not limited to two. The number of well layers may be one or three or more.

P-side clad layer 113 is stacked on active layer 112. In the present embodiment, semiconductor light emitting device 100 includes a plurality of ridges serving as current paths. In the present embodiment, p-side clad layer 113 is a superlattice layer in which 100 layers including AlGaN and having a thickness of 3 nm and 100 layers including GaN and having a thickness of 3 nm are alternately stacked and whose thickness is 0.6 μm. P-side clad layer 113 may be doped with Mg. For example, the concentration of Mg may be 1×10¹⁹ cm⁻³.

The configuration of p-side clad layer 113 is not limited to this configuration. The thickness of p-side clad layer 113 may be greater than or equal to 0.1 μm and less than or equal to 1 μm. The composition of p-side clad layer 113 may be p-AlₓGa₁₋ₓN (0<x<1). The concentration of Mg may be 1×10¹⁹ cm⁻³.

P electrode 114 may be, for example, a single-layer film or a multilayer film which includes at least one of Cr, Ti, Ni, Pd, Pt, and Au. For example, p electrode 114 is a multilayer film (Pd/Pt) in which Pd and Pt are stacked in layers sequentially from the side of p-side clad layer 113, and p electrodes 114 are arranged with an interval (pitch) of 225 μm in second direction D2. The width of p electrode 114 (that is, the width in second direction D2) is, for example, 16 μm.

In the present embodiment of substrate 110, n electrode 116 is a multilayer film (Ti/Pt/Au) in which Ti, Pt, and Au are stacked in layers sequentially from the side of substrate 110. The configuration of n electrode 116 is not limited to this configuration. N electrode 116 may include another conductive material.

Although not shown in the figure, semiconductor light emitting device 100 further includes a current block layer and a p-side pad electrode. The current block layer is an insulating layer which covers the region other than p electrode 114 on the upper surface of semiconductor multilayer 109. The current block layer is, for example, a SiO₂ film, a SiN film, or the like whose thickness is greater than or equal to 100 nm and less than or equal to 500 nm. The current block layer is, for example, a layer whose thickness is 200 nm and which includes SiO₂.

P-side pad electrode is a pad-shaped electrode which covers p electrode 114, and examples thereof include a multilayer film (Ti/Au) in which Ti and Au are stacked in layers, a multilayer film (Ti/Pt/Au) in which Ti, Pt, and Au are stacked in layers, a multilayer film (Ni/Au) in which Ni and Au are stacked in layers, and the like.

An example of the configuration of the semiconductor light emitting device according to the present embodiment is shown in table 1.

TABLE 1

| | | Composition, | Specific Configuration | Another Configuration |
|---|---|---|---|---|
| Sign | Name | Shape | Example | Example |
| 110 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 111 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 112 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 113 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 114 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 116 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 120 | Groove | Cross-sectional | Cross-sectional shape: | |
| | region | shape: tapered, | single-step shape | |
| | | multistep, etc. | Depth: 4 μm | |
| | | | Width: 100 μm | |
| 121 | Groove for | Depth: not reach | Depth from surface: | |
| | forming | active layer | 550 nm | |
| | ridge | | Width: 20 μm | |

### Effects

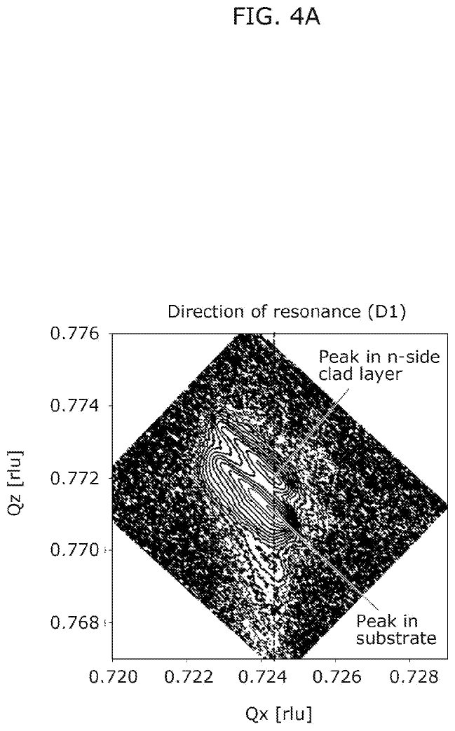

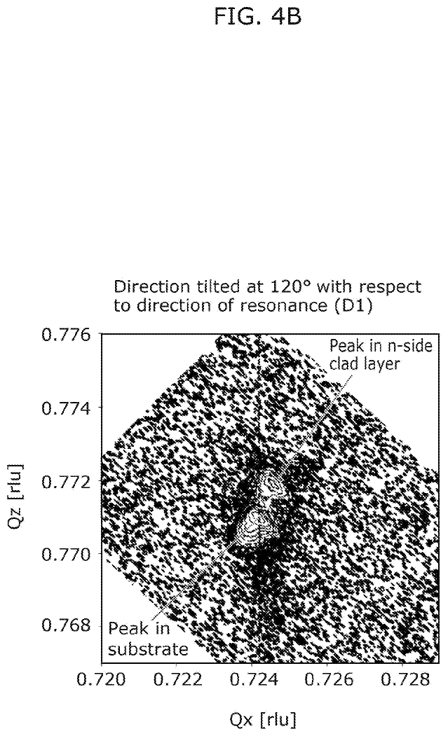

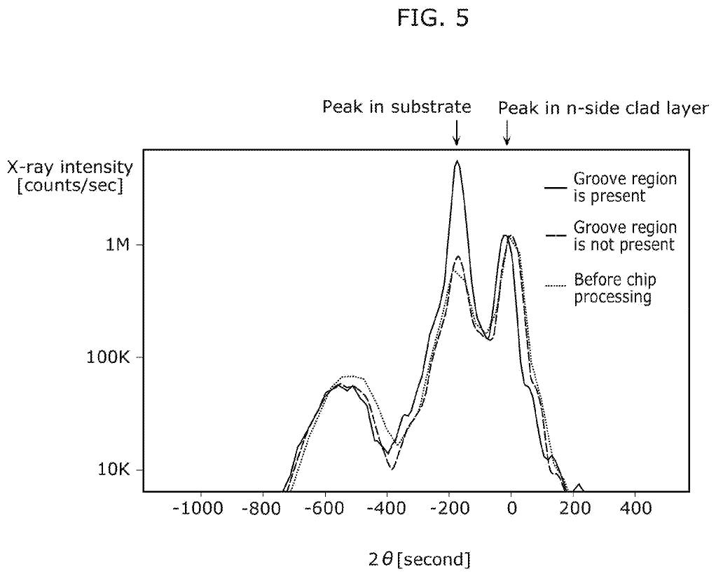

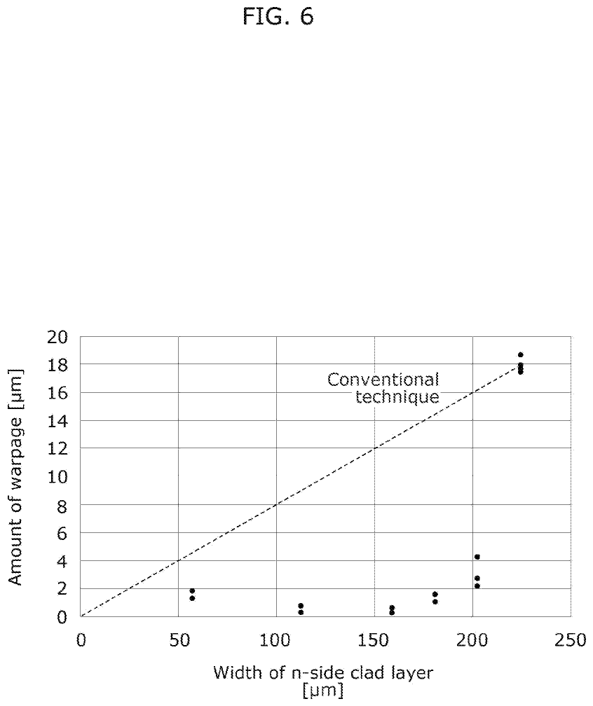

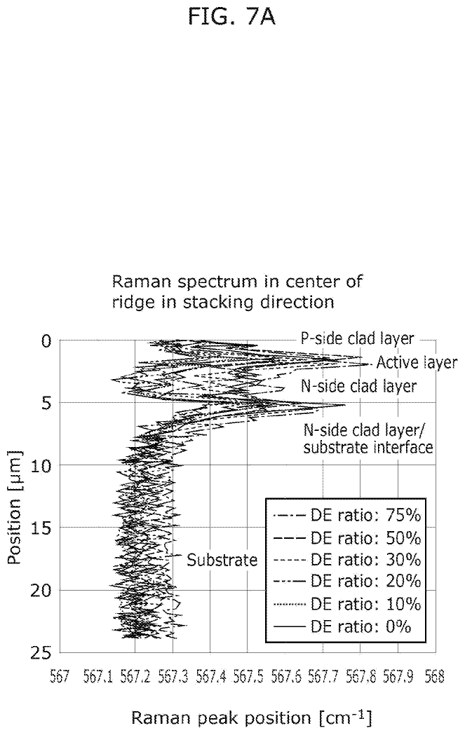

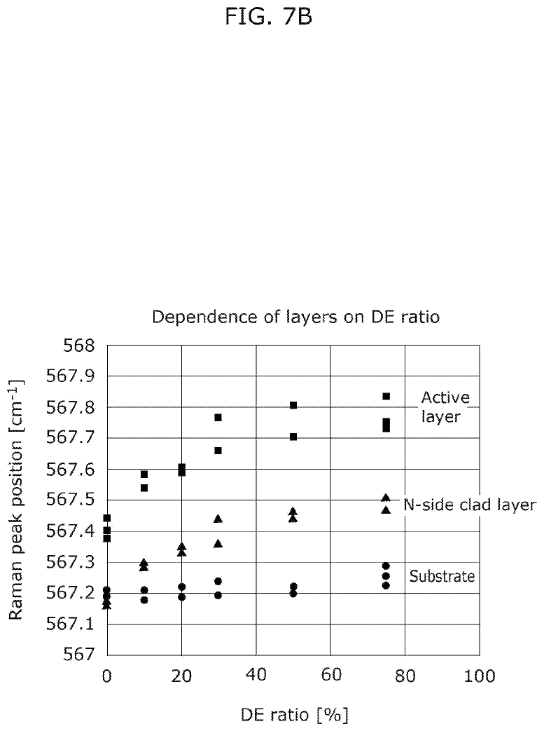

Effects of semiconductor light emitting device 100 according to the present embodiment will then be described using the results of experiments shown in FIGS. 4A to 7B. FIGS. 4A and 4B are graphs showing X-ray reciprocal lattice mapping of semiconductor light emitting device 100 according to the present embodiment in the direction of resonance and in the direction of tilt, respectively. The direction of tilt in FIG. 4B is a direction which is tilted at 120° relative to the direction of resonance. FIG. 5 is a graph showing the result of the measurement of X-ray diffraction (2 θ/w) in semiconductor light emitting device 100 according to the present embodiment. FIG. 6 is a graph showing the result of the measurement of the amount of warpage of semiconductor light emitting device 100 according to the present embodiment. FIG. 6 shows a relationship between the width of n-side clad layer 111 (the width in second direction D2) and the amount of warpage. FIG. 7A and 7B are respectively graphs showing the results of Raman spectrum measurements in semiconductor light emitting device 100 according to the present embodiment. FIG. 7A shows a relationship between a Raman peak position and a position in the stacking direction. FIG. 7A shows the result of the measurements at 6 dry etching (DE) ratios (that is, the ratio of a total of the widths of all groove regions 120 to the width of semiconductor light emitting device 100 in second direction D2). FIG. 7B shows a relationship between the DE ratio and the Raman peak position. FIG. 7B shows the result of the measurements in positions in the stacking direction.

The present inventor performed experiments using the semiconductor light emitting device which included groove regions 120 arranged at regular intervals in second direction D2. The thickness of substrate 110 used in the present experiments was 80 μm, and the thickness of semiconductor multilayer 109 was 4.0 μm. The thickness of n-side clad layer 111 included in semiconductor multilayer 109 was 3.0 μm. The width of semiconductor light emitting device 100 in the direction of resonance and the width in second direction D2 were 2 mm and 9 mm, respectively. The interval between groove regions 120 in second direction D2 was 225 μm. The depth of groove region 120 was 4.5 μm. In other words, in groove regions 120, all of semiconductor multilayers 109 and part of substrate 110 were removed by dry etching.

In the structure described above, anisotropic flexibility in deformation is given to n-side clad layers 111 which are divided by groove regions 120 and which are elongated in the direction of resonance. By the action on n-side clad layers 111 caused by groove regions 120, it is possible to lower flexibility in the deformation of n-side clad layers 111 in the direction of resonance and to increase flexibility in the deformation in the direction of tilt. Consequently, in the direction of resonance, n-side clad layers 111 maintain the same state as before the formation of groove regions 120, and in the direction of tilt, n-side clad layers 111 can approach a free (free-standing) state for the deformation.

By the effects described above, the lattice constant of n-side clad layer 111 is maintained to be substantially the same lattice constant of substrate 110 in the direction of resonance (that is, a difference between the lattice constant of n-side clad layer 111 and the lattice constant of substrate 110 is less than or equal to 0.01% of n-side clad layer 111 or substrate 110). On the other hand, n-side clad layer 111 includes Al, and thus the lattice constant of n-side clad layer 111 in the direction of tilt is less than the lattice constant of substrate 110 which does not include Al.

By the configuration as described above, the relationship represented by formulae (1) and (2) or the relationship represented by formula (3) is established.

The present inventor used the X-ray reciprocal lattice mapping shown in FIGS. 4A and 4B to check the deformation of the crystal structure of n-side clad layer 111 indicated by the relationships described above. The X axis (that is, the horizontal axis) of FIGS. 4A and 4B corresponds to the reciprocal of the lattice constant in the stacking direction of semiconductor multilayer 109, and the Y axis (that is, the vertical axis) of FIGS. 4A and 4B corresponds to the reciprocal of the lattice constant of a plane perpendicular to the stacking direction of semiconductor multilayer 109.

As indicated by the result of the experiment in the direction of resonance in FIG. 4A, a peak position in the direction of the X axis corresponding to the lattice constant of substrate 110 substantially coincides with a peak position in the direction of the X axis corresponding to the lattice constant of n-side clad layer 111. Hence, it is found that the lattice constants of substrate 110 and n-side clad layer 111 in the direction of resonance are substantially the same as each other.

On the other hand, as indicated by the result of the experiment in the direction of tilt in FIG. 4B, a peak position in the direction of the X axis corresponding to the lattice constant of n-side clad layer 111 is higher than a peak position in the direction of the X axis corresponding to the lattice constant of substrate 110. Hence, it is found that the lattice constant of n-side clad layer 111 in the direction of tilt is less than the lattice constant of substrate 110 in the direction of tilt.

The deformation of n-side clad layer 111 in the stacking direction caused by the deformation of the crystal structure in n-side clad layer 111 was checked by the measurement of X-ray diffraction (2 θ/ω) shown in FIG. 5. The measurement of X-ray diffraction was performed on three types of samples that were a wafer which was not formed into a piece immediately after the crystal growth of semiconductor multilayer 109 (that is, before chip processing), a semiconductor light emitting device which was formed into a piece without formation of groove regions 120 and a semiconductor light emitting device which was formed into a piece and in which groove regions 120 were formed.

When the measurement was performed on the three types of samples, it was found that only in the semiconductor light emitting device in which groove regions 120 were formed, the peak position in n-side clad layer 111 was shifted such that its peak was at a higher angle than the peaks in the other samples. This indicates that the lattice constant in a direction tilted relative to the direction of resonance was decreased and that thus the lattice constant in the stacking direction was increased.

In the state of the semiconductor light emitting device in which groove regions 120 are formed as described above, distortion in the direction of tilt which is caused by a lattice mismatch between substrate 110 and semiconductor multilayer 109 that is the cause of the warpage of substrate 110 is reduced as compared with distortion in the direction of resonance.

The present inventor checked the effect of the reduction of the distortion described above by the dependence of the amount of warpage of the semiconductor light emitting device in a direction perpendicular to the direction of resonance on the width of the n-side clad layer shown in FIG. 6 and the dependence of Raman spectra shown on the groove ratio (DE ratio) shown in FIGS. 7A and 7B.

First, since in FIG. 6, the interval between groove regions 120 in the semiconductor light emitting device which is the measurement target is 225 nm, the amount of warpage where the width of the n-side clad layer shown in FIG. 6 is plotted at a point of 225 nm corresponds to the amount of warpage of a semiconductor light emitting device without formation of groove regions 120 (that is, the semiconductor light emitting device of the conventional technique). When the amount of warpage of the semiconductor light emitting device without formation of groove regions 120 as described above is compared with the amount of warpage of the semiconductor light emitting device in which groove regions 120 are formed to reduce the width of the n-side clad layer, it has been confirmed that the amount of warpage is non-linearly lowered relative to the width of the n-side clad layer.

It has been confirmed that as shown in FIG. 6, the width of the n-side clad layer is set less than or equal to about 200 μm and that thus the amount of warpage can be reduced. In the present embodiment, it is said that since the length of the resonator is 2 mm, when the ratio of the length of the resonator to the width of the n-side clad layer (that is, the width of semiconductor multilayer 109 in a direction perpendicular to the direction of resonance and the stacking direction) is greater than or equal to 10, it is possible to reduce the amount of warpage.

Since it is predicted from the conventional technique that the amount of warpage is linearly changed, the result of the measurement shown in FIG. 6 indicates that distortion was reduced in semiconductor light emitting device 100 according to the present disclosure more than in the semiconductor light emitting device of the conventional technique.

The state of stress of semiconductor multilayer 109 was evaluated from the amounts of shift of peak positions in the Raman spectra shown in FIGS. 7A and 7B. In FIG. 7B, the Raman peak positions of substrate 110, n-side clad layer 111, and active layer 112 are represented by a circle, a triangle, and a square, respectively.

When the Raman spectrum in the center of the ridge in the stacking direction (the center of the ridge in second direction D2) was measured, it was confirmed that as shown in FIGS. 7A and 7B (in particular, FIG. 7B), as the groove ratio (DE ratio) was increased, the Raman peak position of n-side clad layer 111 was shifted to the side of a larger number of waves. This indicates that tensile stress (distortion) received by n-side clad layer 111 was reduced. Hence, it was confirmed that the lattice constant of n-side clad layer 111 was decreased, that thus a lattice mismatch between n-side clad layer 111 and substrate 110 was reduced, and that consequently, distortion which caused warpage was reduced. It was also confirmed that a dislocation occurring in an interface between substrate 110 and n-side clad layer 111 (that is, the interface between substrate 110 and semiconductor multilayer 109) was suppressed to, for example, 10⁷ cm⁻² or less.

It has been confirmed by the experiments described above that even when the width of groove region 120 is reduced as compared with the conventional technique, the warpage of the semiconductor light emitting device is sufficiently reduced.

As described above, in semiconductor light emitting device 100 according to the present embodiment, it is possible to realize a laser chip in which the width of groove region 120 is narrow and in which warpage is reduced. For example, when the DE ratio is greater than or equal to 10%, the warpage of semiconductor light emitting device 100 can be reduced. When the DE ratio is greater than or equal to 20%, the warpage of semiconductor light emitting device 100 can be more reduced. When the DE ratio is greater than or equal to 30%, tensile stress received by n-side clad layer 111 can be almost completely alleviated, and thus the warpage of semiconductor light emitting device 100 can be further reduced. In semiconductor light emitting device 100 as described above, even when junction-down mounting is performed, since the width of groove region 120 is narrow, the occurrence of a void in groove region 120 can be suppressed. Hence, a laser chip in which the heat dissipation property and laser properties thereof are satisfactory can be realized.

### Manufacturing Method

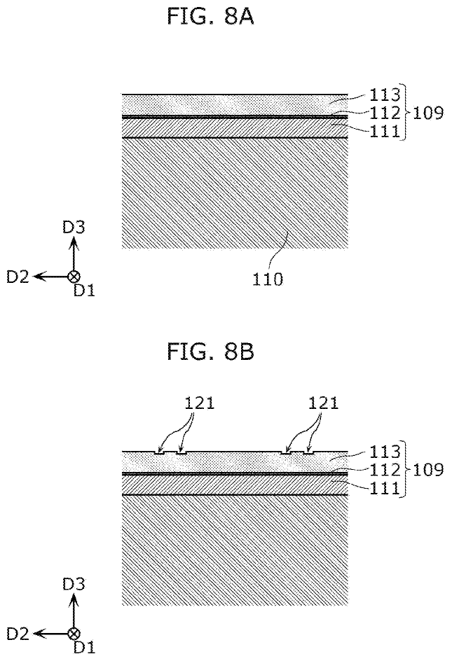

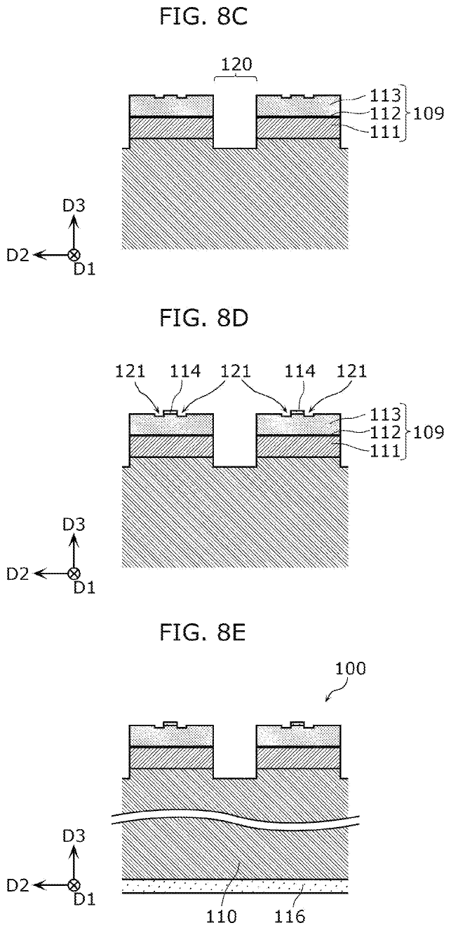

A method of manufacturing semiconductor light emitting device 100 according to the present embodiment will then be described with reference to FIGS. 8A to 8E. FIGS. 8A to 8E are schematic cross-sectional views showing steps in the method of manufacturing semiconductor light emitting device 100 according to the present embodiment. In FIGS. 8A to 8E, cross sections in the same position as in FIG. 2 are shown.

Semiconductor light emitting device 100 according to the present embodiment is manufactured through steps (a) to (f) described below.

(a) As shown in FIG. 8A, a crystal growth technique such as metal-organic chemical vapor deposition (MOCVD) is first used to stack n-side clad layer 111, active layer 112, and p-side clad layer 113 on substrate 110 in this order. In this way, semiconductor multilayer 109 is stacked on substrate 110.

(b) Then, as shown in FIG. 8B, a dry etching technique is used to produce grooves 121 for forming ridges. In this way, the ridge is formed between two grooves 121.

(c) Then, as shown in FIG. 8C, the dry etching technique is used to form groove region 120 between two adjacent ridges.

(d) Then, as shown in FIG. 8D, photolithography and a vacuum deposition technique are used to form p electrodes 114 on the ridges. Although not shown in the figure, regions other than p electrodes 114 are covered with a current block layer including a dielectric. Furthermore, although not shown in the figure, a p-side pad electrode is formed on p electrodes 114 and the current block layer.

(e) Then, as shown in FIG. 8E, the photolithography and the vacuum deposition technique are used to form n electrode 116 on the back surface (lower surface in FIG. 8E) of substrate 110.

(f) Then, semiconductor light emitting device 100 is cut out by cleavage or dicing. In other words, a plurality of semiconductor light emitting devices 100 formed on a wafer are formed into pieces.

### Embodiment 2

A semiconductor light emitting device according to embodiment 2 will then be described. The semiconductor light emitting device according to the present embodiment differs from semiconductor light emitting device 100 according to embodiment 1 in the configuration of the groove region. The semiconductor light emitting device according to the present embodiment will be described below mainly on differences from semiconductor light emitting device 100 according to embodiment 1.

### Configuration

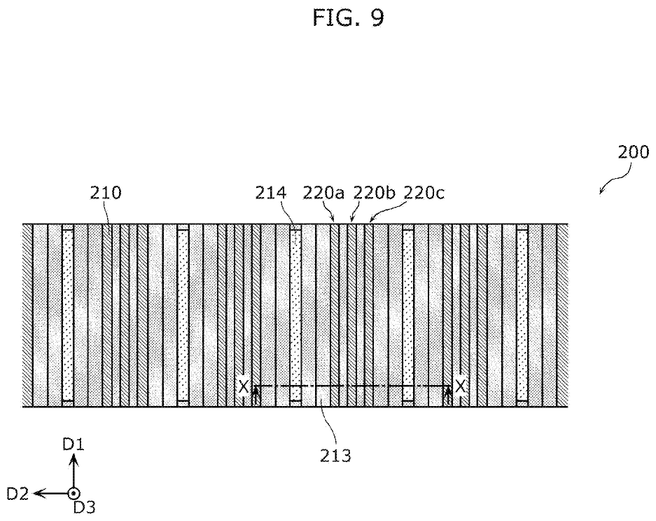

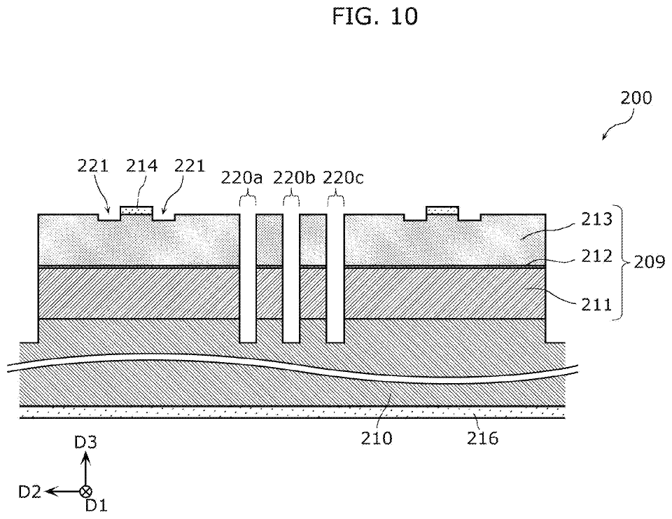

The configuration of the semiconductor light emitting device according to the present embodiment will first be described with reference to FIGS. 9 and 10. FIGS. 9 and 10 are respectively a schematic top view and a schematic cross-sectional view of semiconductor light emitting device 200 according to the present embodiment. FIG. 10 shows a cross section taken along line X-X in FIG. 9.

Semiconductor light emitting device 200 is a laser chip including a GaN-based material and the like, and includes, as shown in FIG. 10, substrate 210 and semiconductor multilayers 209 stacked on substrate 210. In the present embodiment, semiconductor light emitting device 200 further includes p electrodes 214 and n electrode 216. Although not shown in the figure, semiconductor light emitting device 200 further includes, as with semiconductor light emitting device 100 according to embodiment 1, a p-side pad electrode and a current block layer.

Semiconductor multilayer 209 includes n-side clad layer 211 which is stacked above substrate 210, active layer 212 which is stacked above n-side clad layer 211, and p-side clad layer 213 which is stacked above active layer 212.

Semiconductor light emitting device 200 includes a plurality of p electrodes 214 arranged on p-side clad layer 213. A current is injected between p electrodes 214 and n electrode 216 provided on the back surface of substrate 210.

Semiconductor light emitting device 200 includes one or more resonators. In the present embodiment, semiconductor light emitting device 200 is a laser array which includes a plurality of resonators. In the regions of p-side clad layer 213 located on the sides of p electrode 214, a pair of grooves 221 are provided which extend parallel to the direction of resonance. In this way, in p-side clad layer 213 of semiconductor multilayer 209, a ridge for confining the light and the current can be formed.

In the present embodiment, semiconductor light emitting device 200 includes one or more groove regions which are arranged above substrate 210 and which extend parallel to the direction of resonance. When semiconductor light emitting device 200 includes a plurality of semiconductor multilayers 209, between one semiconductor multilayer 209 and other semiconductor multilayers 209, the groove region deeper than groove 221 for forming the ridge is formed. In the present embodiment, semiconductor light emitting device 200 includes, for example, three groove regions 220a, 220b, and 220c between two adjacent resonators. In other words, semiconductor light emitting device 200 has a concavo-convex structure which includes a plurality of groove regions 220a, 220b, and 220c between two adjacent resonators. For example, in semiconductor light emitting device 200, the number of semiconductor multilayers 209 may be less than the number of groove regions.

Groove regions 220a, 220b, and 220c may reach substrate 210.

When in the present embodiment, the direction of tilt in a first plane included in n-side clad layer 211 and the direction of tilt in a second plane included in substrate 210 are assumed to be a direction which is tilted at 60 degrees or 120 degrees relative to the direction of resonance, as in embodiment 1, the relationship represented by formulae (1) and (2) or the relationship represented by formula (3) is established.

In the present embodiment, the depth of each of groove regions 220a, 220b, and 220c reaches substrate 210. The depth of each of groove regions 220a, 220b, and 220c is, for example, 4 μm from the surface of semiconductor light emitting device 200. Although the width of each of groove regions 220a, 220b, and 220c is not particularly limited, the width is, for example, 30 μm. Each of an interval between groove region 220a and groove region 220b and an interval between groove region 220b and groove region 220c is, for example, 30 μm. In other words, the width of the concavo-convex structure (the width in second direction D2) including the three groove regions is 150 μm.

An example of the configuration of semiconductor light emitting device 200 according to the present embodiment is shown in table 2.

TABLE 2

| | | Composition, | Specific Configuration | Another Configuration |
|---|---|---|---|---|
| Sign | Name | Shape | Example | Example |
| 210 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 211 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 212 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 213 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 214 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 216 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 220a | Groove | Cross-sectional | Cross-sectional shape: | |
| | region | shape: tapered, | single-step shape | |
| | | multistep, etc. | Depth: 4 μm | |
| | | | Width: 30 μm | |
| 220b | Groove | Cross-sectional | Cross-sectional shape: | |
| | region | shape: tapered, | single-step shape | |
| | | multistep, etc. | Depth: 4 μm | |
| | | | Width: 30 μm | |
| 220c | Groove | Cross-sectional | Cross-sectional shape: | |
| | region | shape: tapered, | single-step shape | |
| | | multistep, etc. | Depth: 4 μm | |
| | | | Width: 30 μm | |

### Effects

Effects of semiconductor light emitting device 200 according to the present embodiment will then be described. Since in semiconductor light emitting device 200 according to the present embodiment, it is possible to reduce distortion, in the direction of tilt, of n-side clad layer 211 adjacent in second direction D2 to a plurality of groove regions, the warpage of semiconductor light emitting device 200 in a direction perpendicular to the direction of resonance can be reduced while the volume of n-side clad layer 211 in the concavo-convex structure is being increased.

Consequently, even when junction-down mounting is performed, the occurrence of a void in each of the groove regions can be suppressed, and thus a laser chip in which the heat dissipation property and laser properties thereof are satisfactory can be realized.

### Manufacturing Method

A method of manufacturing semiconductor light emitting device 200 according to the present embodiment is the same as the method of manufacturing semiconductor light emitting device 100 according to embodiment 1.

### Embodiment 3

A semiconductor light emitting device according to embodiment 3 will be described. The semiconductor light emitting device according to the present embodiment differs from semiconductor light emitting device 100 according to embodiment 1 in that a smaller number of groove regions are provided. The semiconductor light emitting device according to the present embodiment will be described below mainly on differences from semiconductor light emitting device 100 according to embodiment 1.

### Configuration

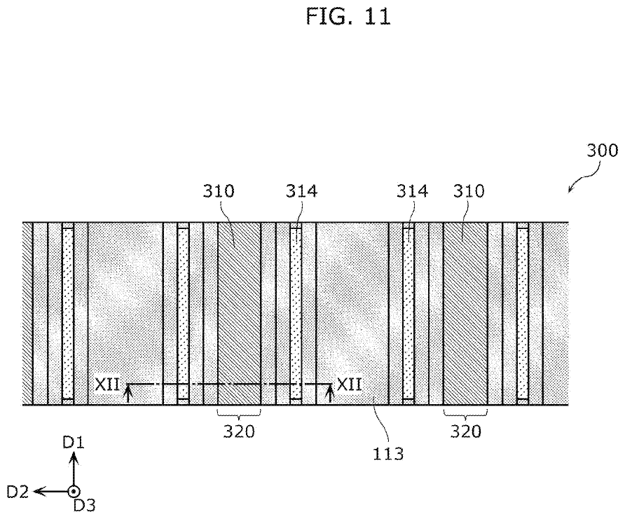

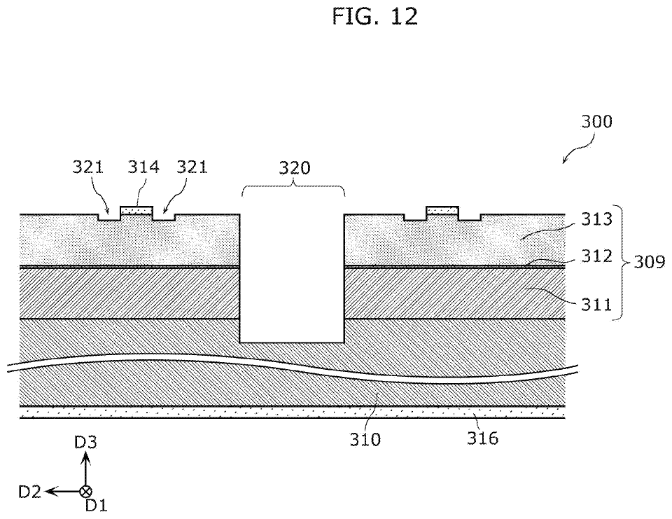

The configuration of the semiconductor light emitting device according to the present embodiment will first be described with reference to FIGS. 11 and 12. FIGS. 11 and 12 are respectively a schematic top view and a schematic cross-sectional view of semiconductor light emitting device 300 according to the present embodiment. FIG. 12 shows a cross section taken along line XII-XII in FIG. 11.

Semiconductor light emitting device 300 is a laser chip including a GaN-based material and the like, and includes, as shown in FIG. 12, substrate 310 and semiconductor multilayers 309 stacked on substrate 310. In the present embodiment, semiconductor light emitting device 300 further includes p electrodes 314 and n electrode 316. Although not shown in the figure, semiconductor light emitting device 300 further includes, as with semiconductor light emitting device 100 according to embodiment 1, a p-side pad electrode and a current block layer. Semiconductor multilayer 309 includes n-side clad layer 311 which is stacked above substrate 310, active layer 312 which is stacked above n-side clad layer 311, and p-side clad layer 313 which is stacked above active layer 312.

Semiconductor light emitting device 300 includes a plurality of p electrodes 314 arranged on p-side clad layer 313. A current is injected between p electrodes 314 and n electrode 316 provided on the back surface of substrate 310.

Semiconductor light emitting device 300 includes one or more resonators. In the present embodiment, semiconductor light emitting device 300 is a laser array which includes a plurality of resonators. In the regions of p-side clad layer 313 located on the sides of p electrode 314, a pair of grooves 321 are provided which extend parallel to the direction of resonance. In this way, in p-side clad layer 313 of semiconductor multilayer 309, a ridge for confining the light and the current can be formed.

In the present embodiment, semiconductor light emitting device 300 includes one or more groove regions 320 which are arranged above substrate 310 and which extend parallel to the direction of resonance. When semiconductor light emitting device 300 includes a plurality of semiconductor multilayers 309, between one semiconductor multilayer 309 and other semiconductor multilayers 309, groove region 320 deeper than groove 321 for forming the ridge is formed. In the present embodiment, as shown in FIG. 11, between two p electrodes 314 adjacent in second direction D2, groove region 320 is not necessarily formed. In other words, the number of groove regions 320 in the present embodiment is less than the number of resonators. Preferably, for example, groove region 320 is formed on at least one of the sides (second direction D2) of the resonator.

When in semiconductor light emitting device 300 according to the present embodiment, the direction of tilt in a first plane included in n-side clad layer 311 and the direction of tilt in a second plane included in substrate 310 are assumed to be a direction which is tilted at 60 degrees or 120 degrees relative to the direction of resonance, as in embodiment 1, the relationship represented by formulae (1) and (2) or the relationship represented by formula (3) is established.

An example of the configuration of the semiconductor light emitting device according to the present embodiment is shown in table 3.

TABLE 3

| | | Composition, | Specific Configuration | Another Configuration |
|---|---|---|---|---|
| Sign | Name | Shape | Example | Example |
| 310 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 311 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 312 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 313 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 314 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 316 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 320 | Groove | Cross-sectional | Cross-sectional shape: | |
| | region | shape: tapered, | single-step shape | |
| | | multistep, etc. | Depth: 4 μm | |
| | | | Width: 100 μm | |

### Effects

Effects of semiconductor light emitting device 300 according to the present embodiment will then be described. Since in semiconductor light emitting device 300 according to the present embodiment, it is possible to reduce distortion, in a direction perpendicular to the direction of resonance, of n-side clad layer 311 sandwiched between two adjacent groove regions 320, the warpage of semiconductor light emitting device 300 in the direction perpendicular to the direction of resonance can be reduced while the volume of n-side clad layer 311 included in semiconductor light emitting device 300 is being increased.

Consequently, even when junction-down mounting is performed, the occurrence of a void in groove region 320 can be suppressed, and thus a laser chip in which the heat dissipation property and laser properties thereof are satisfactory can be realized.

### Manufacturing Method

A method of manufacturing semiconductor light emitting device 300 according to the present embodiment is the same as the method of manufacturing semiconductor light emitting device 100 according to embodiment 1.

### Embodiment 4

A semiconductor light emitting device according to embodiment 4 will be described. The semiconductor light emitting device according to the present embodiment differs from semiconductor light emitting device 100 according to embodiment 1 in the inclusion of a single resonator and the composition of the active layer. The semiconductor light emitting device according to the present embodiment will be described below mainly on differences from semiconductor light emitting device 100 according to embodiment 1.

### Configuration

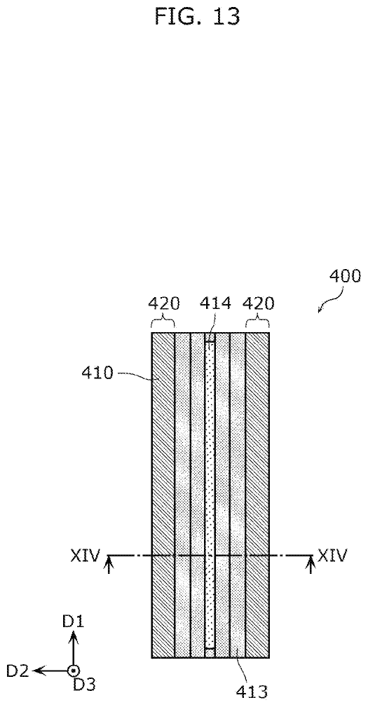

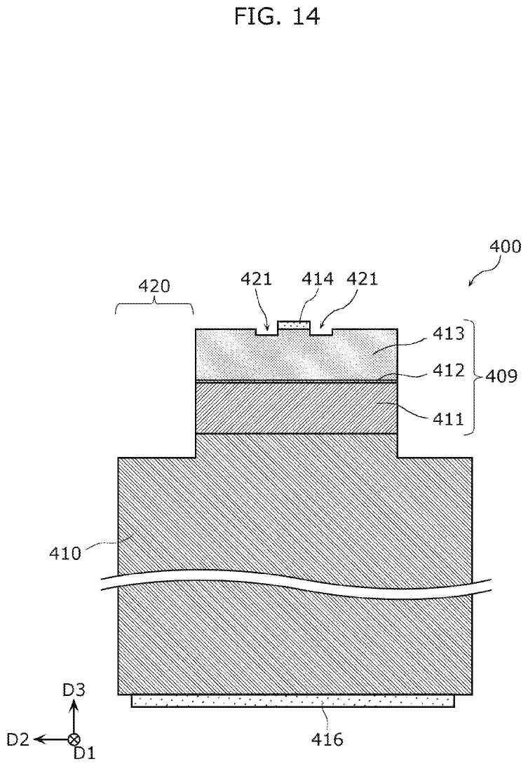

The configuration of the semiconductor light emitting device according to the present embodiment will first be described with reference to FIGS. 13 and 14. FIGS. 13 and 14 are respectively a schematic top view and a schematic cross-sectional view of semiconductor light emitting device 400 according to the present embodiment. FIG. 14 shows a cross section taken along line XIV-XIV in FIG. 13.

Semiconductor light emitting device 400 is a laser chip including a GaN-based material and the like, and includes, as shown in FIG. 14, substrate 410 and semiconductor multilayer 409 stacked on substrate 410. In the present embodiment, semiconductor light emitting device 400 further includes p electrode 414 and n electrode 416. Although not shown in the figure, semiconductor light emitting device 400 further includes, as with semiconductor light emitting device 100 according to embodiment 1, a p-side pad electrode and a current block layer. Semiconductor multilayer 409 includes n-side clad layer 411 which is stacked above substrate 410, active layer 412 which is stacked above n-side clad layer 411, and p-side clad layer 413 which is stacked above active layer 412. In the present embodiment, semiconductor light emitting device 400 includes single p electrode 414 arranged on p-side clad layer 413. A current is injected between p electrode 414 and n electrode 416 provided on the back surface of substrate 410.

Active layer 412 in the present embodiment includes at least Al. Active layer 412 has a quantum well structure, and the composition of each of a well layer and a barrier layer is represented by AlₓIn_{y}GaN (0≤x,y). The band gap of active layer 412 is larger than the band gap of GaN and is smaller than the band gap of each of n-side clad layer 411 and p-side clad layer 413. Active layer 412 is a quantum well active layer in which the well layer including AlₓIn_{y}GaN (0≤x,y) and the barrier layer including AlₓIn_{y}GaN (0≤x,y) are alternately stacked, and includes, for example, two well layers. For example, the well layer includes Al_{0.06}GaN, and the barrier layer includes Al_{0.10}GaN. The number of well layers is not limited to two, and may be one or three or more.

As described above, semiconductor light emitting device 400 according to the present embodiment is a single emitter laser chip which includes a single resonator. In the regions of p-side clad layer 413 located on the sides of p electrode 414, a pair of grooves 421 are provided which extend parallel to the direction of resonance. In this way, in p-side clad layer 413, a ridge for confining the light and the current can be formed.

Semiconductor light emitting device 400 includes one or more groove regions 420 which are arranged above substrate 410 and which extend parallel to the direction of resonance. In the present embodiment, at least one or more groove regions 420 are provided outside grooves 421 for forming the ridge in second direction D2. Groove region 420 is not necessarily limited to part which is sandwiched between a pair of side walls and which has a concave shape, and groove region 420 may be part which has a step-shaped (or staircase-shaped) cross-sectional view as shown in FIG. 14. Groove region 420 may reach substrate 410. The depth of groove region 420 is, for example, 2 μm from the surface of semiconductor light emitting device 400. Although the width of groove region 420 is not particularly limited, the width is, for example, 50 μm.

When in semiconductor light emitting device 400 according to the present embodiment having the configuration as described above, the direction of tilt in a first plane included in n-side clad layer 411 and the direction of tilt in a second plane included in substrate 410 are assumed to be a direction which is tilted at 60 degrees or 120 degrees relative to the direction of resonance, as in embodiment 1, the relationship represented by formulae (1) and (2) or the relationship represented by formula (3) is established.

An example of the configuration of semiconductor light emitting device 400 according to the present embodiment is shown in table 4.

TABLE 4

| | | Composition, | Specific Configuration | Another Configuration |
|---|---|---|---|---|
| Sign | Name | Shape | Example | Example |
| 410 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 0.2 mm × 1.2 mm | used instead. |
| 411 | N-side clad | Composition: | Composition: Al_{0.10}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 1 μm | |
| | | or more | | |
| 412 | Active layer | Composition: | Composition: Al_{0.06}GaN/ | |
| | | AlₓIn_{y}GaN | Al_{0.10}GaN | |
| | | (x, y ≥ 0)/ | (quantum well structure) | |
| | | AlₓIn_{y}GaN | Thickness: 5 nm/10 nm | |
| | | (x, y ≥ 0) | Number of wells: 2 | |
| | | (quantum well | | |
| | | structure) | | |
| 413 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 10% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 414 | P electrode | Composition: at | Composition: Pd/Pt | Multilayer film can be |
| | | least one of Cr, Ti, | Width: 16 μm | used. |
| | | Ni, Pd, Pt, and Au | | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 416 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 420 | Groove | Cross-sectional | Cross-sectional shape: | |
| | region | shape: tapered, | single-step shape | |
| | | multistep, etc. | Depth: 2 μm | |
| | | | Width: 50 μm | |

### Effects

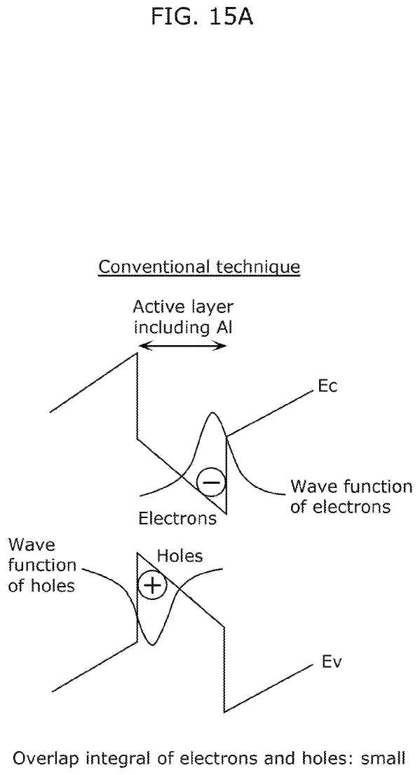

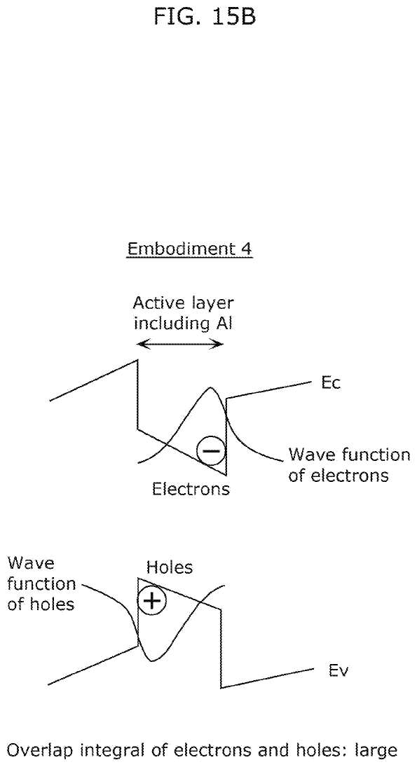

Effects of semiconductor light emitting device 400 according to the present embodiment will then be described with reference to FIGS. 15A and 15B. FIGS. 15A and 15B are respectively a diagram schematically showing a relationship between the energy band structure of the semiconductor light emitting device of the conventional technique and the distortion of an active layer and a diagram schematically showing a relationship between the energy band structure of the semiconductor light emitting device according to the present embodiment and the distortion of the active layer. In FIGS. 15A and 15B, the energy levels of a conduction band and a valence band are represented by Ec and Ev, respectively.

The semiconductor light emitting device of the conventional technique differs from semiconductor light emitting device 400 according to the present embodiment in that no groove region is formed, and is the same as semiconductor light emitting device 400 in the other respects.

The active layer in the semiconductor light emitting device of the conventional technique has a lattice mismatch for a substrate. Hence, the active layer is in a state where tensile distortion is applied thereto. Therefore, an electric field caused by the distortion is generated inside the active layer. Consequently, as shown in FIG. 15A, the gradient of an energy band structure is steep, and thus electrons and holes are spatially isolated. Hence, the overlap integral of the wave function of electrons and holes is decreased, and thus recombination efficiency is lowered. The efficiency of light emission of the semiconductor light emitting device is lowered accordingly.

On the other hand, in semiconductor light emitting device 400 according to the present embodiment, the lattice constant of n-side clad layer 411 in the direction of tilt is decreased, and thus tensile distortion applied to active layer 412 is less than the tensile distortion in the conventional technique. Hence, the electric field caused by the internal distortion is reduced. Consequently, the overlap integral of the wave function of electrons and holes is increased, and thus recombination efficiency is increased. Therefore, the efficiency of light emission of semiconductor light emitting device 400 is enhanced.

Since in the present embodiment, it is possible to reduce distortion, in a direction perpendicular to the direction of resonance, of n-side clad layer 411 sandwiched between two groove regions 420, the warpage of semiconductor light emitting device 400 in the direction perpendicular to the direction of resonance can be reduced while the volume of n-side clad layer 411 included in semiconductor light emitting device 400 is being increased.

Consequently, even when junction-down mounting is performed, the occurrence of a void in groove region 420 can be suppressed, and thus a laser chip in which the heat dissipation property and laser properties thereof are satisfactory can be realized.

### Manufacturing Method

A method of manufacturing semiconductor light emitting device 400 according to the present embodiment is the same as the method of manufacturing semiconductor light emitting device 100 according to embodiment 1.

### Embodiment 5

A semiconductor light emitting device according to embodiment 5 will be described. The semiconductor light emitting device according to the present embodiment differs from semiconductor light emitting device 400 according to embodiment 4 in the composition of the active layer and the shape of the groove region. The semiconductor light emitting device according to the present embodiment will be described below mainly on differences from semiconductor light emitting device 400 according to embodiment 4.

### Configuration

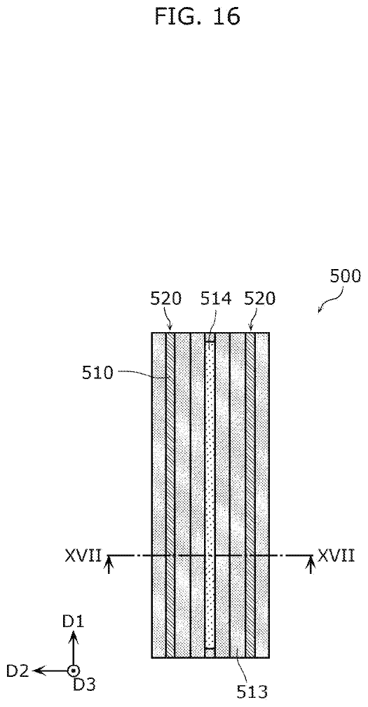

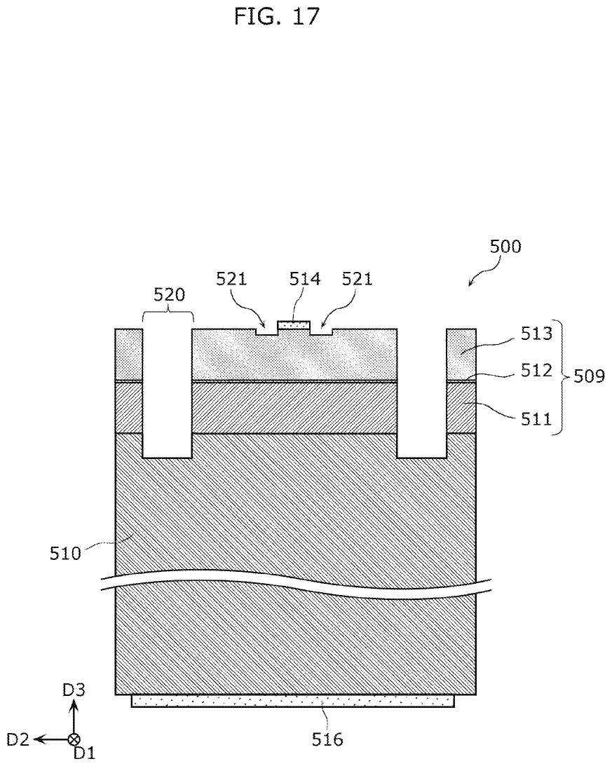

The configuration of the semiconductor light emitting device according to the present embodiment will first be described with reference to FIGS. 16 and 17. FIGS. 16 and 17 are respectively a schematic top view and a schematic cross-sectional view of semiconductor light emitting device 500 according to the present embodiment. FIG. 17 shows a cross section taken along line XVII-XVII in FIG. 16.

Semiconductor light emitting device 500 is a laser chip including a GaN-based material and the like, and includes, as shown in FIG. 17, substrate 510 and semiconductor multilayers 509 stacked on substrate 510. In the present embodiment, semiconductor light emitting device 500 further includes p electrode 514 and n electrode 516. Although not shown in the figure, semiconductor light emitting device 500 further includes, as with semiconductor light emitting device 100 according to embodiment 1, a p-side pad electrode and a current block layer. Semiconductor multilayer 509 includes n-side clad layer 511 which is stacked above substrate 510, active layer 512 which is stacked above n-side clad layer 511, and p-side clad layer 513 which is stacked above active layer 512. In the present embodiment, semiconductor light emitting device 500 includes single p electrode 514 arranged on p-side clad layer 513. A current is injected between p electrode 514 and n electrode 516 provided on the back surface of substrate 510.

Unlike active layer 412 in embodiment 4, active layer 512 in the present embodiment does not include Al. For example, active layer 512 has the same configuration as active layer 112 in embodiment 1 or the like.

Semiconductor light emitting device 500 according to the present embodiment is a single emitter laser chip which includes a single resonator. In the regions of p-side clad layer 513 located on the sides of p electrode 514, a pair of grooves 521 are provided which extend parallel to the direction of resonance. In this way, in p-side clad layer 513, a ridge for confining the light and the current can be formed.

Semiconductor light emitting device 500 includes one or more groove regions 520 which are arranged above substrate 510 and which extend parallel to the direction of resonance. In the present embodiment, at least one or more groove regions 520 are provided outside grooves 521 for forming the ridge in second direction D2. The width of groove region 520 in the present embodiment in second direction D2 is less than the width of groove region 420 in embodiment 4 in second direction D2, and semiconductor multilayers 509 are arranged not only inside but also outside groove regions 420 in second direction D2.

Groove region 520 may reach substrate 510, and is deeper than at least active layer 512 to reach n-side clad layer 511. The depth of groove region 520 is, for example, 4 μm from the surface of semiconductor light emitting device 500. Although the width of groove region 520 is not particularly limited, the width is, for example, 30 μm.

When in semiconductor light emitting device 500 according to the present embodiment having the configuration as described above, the direction of tilt in a first plane included in n-side clad layer 511 and the direction of tilt in a second plane included in substrate 510 are assumed to be a direction which is tilted at 60 degrees or 120 degrees relative to the direction of resonance, as in embodiment 1, the relationship represented by formulae (1) and (2) or the relationship represented by formula (3) is established.

An example of the configuration of semiconductor light emitting device 500 according to the present embodiment is shown in table 5.

TABLE 5

| | | Composition, | Specific Configuration | Another Configuration |
|---|---|---|---|---|
| Sign | Name | Shape | Example | Example |
| 510 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 0.2 mm × 1.2 mm | used instead. |
| 511 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 512 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 513 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 514 | P electrode | Composition: at | Composition: Pd/Pt | Multilayer film can be |
| | | least one of Cr, Ti, | Width: 16 μm | used. |
| | | Ni, Pd, Pt, and Au | | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 516 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 520 | Groove | Cross-sectional | Cross-sectional shape: | |
| | region | shape: tapered, | single-step shape | |
| | | multistep, etc. | Depth: 4 μm | |
| | | | Width: 30 μm | |

### Effects

Effects of semiconductor light emitting device 500 according to the present embodiment will then be described. Since in semiconductor light emitting device 500 according to the present embodiment, it is possible to reduce distortion, in a direction perpendicular to the direction of resonance, of n-side clad layer 511 sandwiched between two groove regions 520, the warpage of semiconductor light emitting device 500 in the direction perpendicular to the direction of resonance can be reduced while the volume of n-side clad layer 511 included in semiconductor light emitting device 500 is being increased.

Consequently, even when junction-down mounting is performed, the occurrence of a void in groove region 520 can be suppressed, and thus a laser chip in which the heat dissipation property and laser properties thereof are satisfactory can be realized.

If groove region 520 reaches an end of semiconductor light emitting device 500 in second direction D2, when junction-down mounting is performed, semiconductor light emitting device 500 is easily tilted, with the result that yield in the mounting is lowered. On the other hand, since in the present embodiment, semiconductor multilayers 509 are arranged at the ends of semiconductor light emitting device 500 in second direction D2, semiconductor light emitting device 500 can be supported at two or more places at the time of junction-down mounting, with the result that it is possible to reduce the tilt of semiconductor light emitting device 500 at the time of junction-down mounting. Hence, the yield in the mounting can be enhanced.

### Manufacturing Method

A method of manufacturing semiconductor light emitting device 500 according to the present embodiment is the same as the method of manufacturing semiconductor light emitting device 100 according to embodiment 1.

### Embodiment 6

A semiconductor light emitting device according to embodiment 6 will be described. The semiconductor light emitting device according to the present embodiment differs from semiconductor light emitting device 100 according to embodiment 1 in the shape of the groove region. The semiconductor light emitting device according to the present embodiment will be described below mainly on differences from semiconductor light emitting device 100 according to embodiment 1.

### Configuration

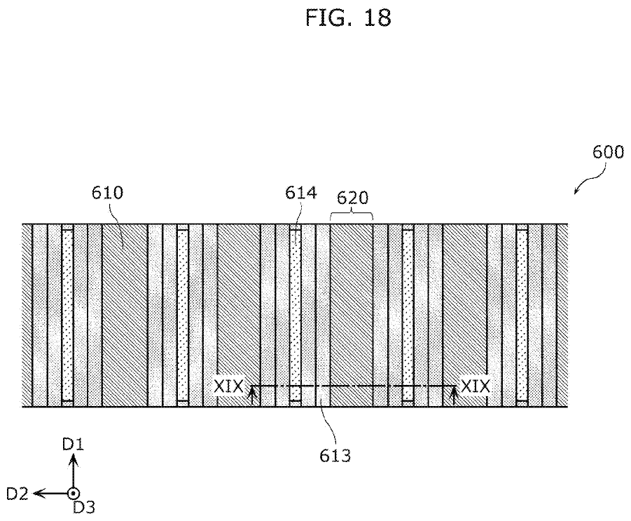

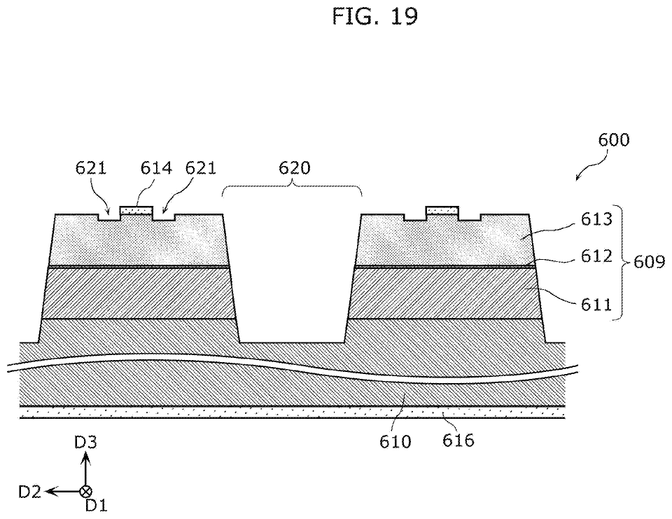

The configuration of the semiconductor light emitting device according to the present embodiment will first be described with reference to FIGS. 18 and 19. FIGS. 18 and 19 are respectively a schematic top view and a schematic cross-sectional view of semiconductor light emitting device 600 according to the present embodiment. FIG. 19 shows a cross section taken along line XIX-XIX in FIG. 18.

Semiconductor light emitting device 600 is a laser chip including a GaN-based material and the like, and includes, as shown in FIG. 19, substrate 610 and semiconductor multilayers 609 stacked on substrate 610. In the present embodiment, semiconductor light emitting device 600 further includes p electrodes 614 and n electrode 616. Although not shown in the figure, semiconductor light emitting device 600 further includes, as with semiconductor light emitting device 100 according to embodiment 1, a p-side pad electrode and a current block layer. Semiconductor multilayer 609 includes n-side clad layer 611 which is stacked above substrate 610, active layer 612 which is stacked above n-side clad layer 611, and p-side clad layer 613 which is stacked above active layer 612. In the present embodiment, semiconductor light emitting device 600 includes a plurality of p electrodes 614 arranged on p-side clad layers 613. A current is injected between p electrodes 614 and n electrode 616 provided on the back surface of substrate 610.

Semiconductor light emitting device 600 includes one or more resonators. In the present embodiment, semiconductor light emitting device 600 is a laser array which includes a plurality of resonators. In the regions of p-side clad layer 613 located on the sides of p electrode 614, a pair of grooves 621 are provided which extend parallel to the direction of resonance. In this way, in p-side clad layer 613 of semiconductor multilayer 609, a ridge for confining the light and the current can be formed.

In the present embodiment, semiconductor light emitting device 600 includes one or more groove regions 620 which are arranged above substrate 610 and which extend parallel to the direction of resonance. When semiconductor light emitting device 600 includes a plurality of semiconductor multilayers, between one semiconductor multilayer 609 and other semiconductor multilayers 609, groove region 620 deeper than groove 621 for forming the ridge is formed. The depth of groove region 620 may reach substrate 610. For example, the depth of groove region 620 is 4 μm from the surface of semiconductor light emitting device 600. The shape of groove region 620 may be such a tapered shape that as the groove deepens, the width is decreased toward the end in the cross section shown in FIG. 19. Although the width of groove region 620 is not particularly limited, the width is, for example, 100 μm at the narrowest part.

When in semiconductor light emitting device 600 according to the present embodiment, the direction of tilt in a first plane included in n-side clad layer 611 and the direction of tilt in a second plane included in substrate 610 are assumed to be a direction which is tilted at 60° or 120° relative to the direction of resonance, as in embodiment 1, the relationship represented by formulae (1) and (2) or the relationship represented by formula (3) is established.

An example of the configuration of semiconductor light emitting device 600 according to the present embodiment is shown in table 6.

TABLE 6

| | | Composition, | Specific Configuration | Another Configuration |
|---|---|---|---|---|
| Sign | Name | Shape | Example | Example |
| 610 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 611 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 612 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 613 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 614 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 616 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 620 | Groove | Cross-sectional | Cross-sectional shape: | |
| | region | shape: tapered, | single-step shape, normal | |
| | | multistep, etc. | tapered | |
| | | | Depth: 4 μm | |
| | | | Width: 100 μm | |

### Effects

Effects of semiconductor light emitting device 600 according to the present embodiment will then be described. Since in semiconductor light emitting device 600 according to the present embodiment, it is possible to reduce distortion, in a direction perpendicular to the direction of resonance, of n-side clad layer 611 sandwiched between two groove regions 620, the warpage of semiconductor light emitting device 600 in the direction perpendicular to the direction of resonance can be reduced while the volume of n-side clad layer 611 included in semiconductor light emitting device 600 is being increased.

Consequently, even when junction-down mounting is performed, the occurrence of a void in groove region 620 can be suppressed, and thus a laser chip in which the heat dissipation property and laser properties thereof are satisfactory can be realized.

In the present embodiment, groove region 620 has the tapered shape, and thus the side walls of groove region 620 are tilted, with the result that the rate of coverage at the time of film formation of the current block layer and the p-side pad electrode is increased. Consequently, a leak through a step disconnection can be reduced, and thus a highly reliable laser chip can be realized.

### Manufacturing Method

A method of manufacturing semiconductor light emitting device 600 according to the present embodiment is the same as the method of manufacturing semiconductor light emitting device 100 according to embodiment 1.

### Embodiment 7

A semiconductor light emitting device according to embodiment 7 will be described. The semiconductor light emitting device according to the present embodiment differs from semiconductor light emitting device 100 according to embodiment 1 in the depth of the groove region. The semiconductor light emitting device according to the present embodiment will be described below mainly on differences from semiconductor light emitting device 100 according to embodiment 1.

### Configuration

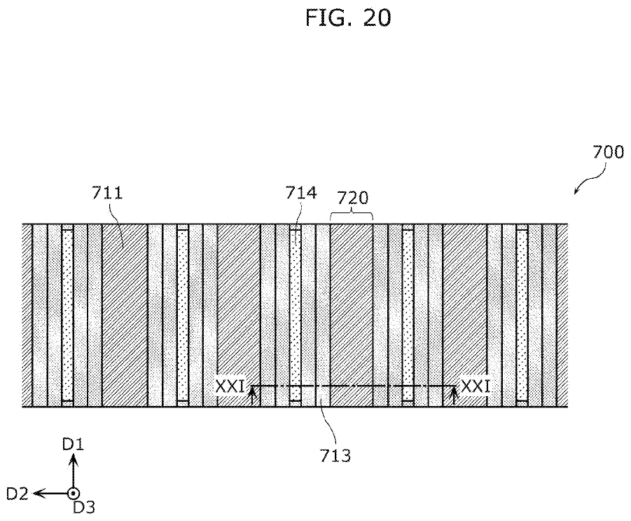

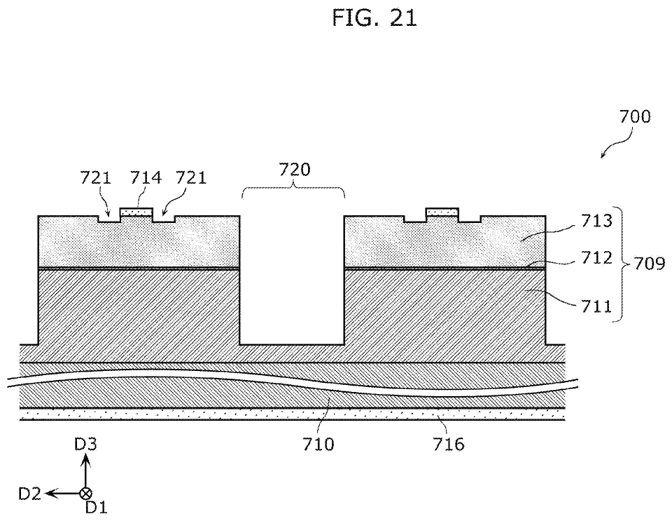

The configuration of the semiconductor light emitting device according to the present embodiment will first be described with reference to FIGS. 20 and 21. FIGS. 20 and 21 are respectively a schematic top view and a schematic cross-sectional view of semiconductor light emitting device 700 according to the present embodiment. FIG. 21 shows a cross section taken along line XXI-XXI in FIG. 20.

Semiconductor light emitting device 700 is a laser chip including a GaN-based material and the like, and includes, as shown in FIG. 21, substrate 710 and semiconductor multilayers 709 stacked on substrate 710. In the present embodiment, semiconductor light emitting device 700 further includes p electrodes 714 and n electrode 716. Although not shown in the figure, semiconductor light emitting device 700 further includes, as with semiconductor light emitting device 100 according to embodiment 1, a p-side pad electrode and a current block layer. Semiconductor multilayer 709 includes n-side clad layer 711 which is stacked above substrate 710, active layer 712 which is stacked above n-side clad layer 711, and p-side clad layer 713 which is stacked above active layer 712. In the present embodiment, semiconductor light emitting device 700 includes a plurality of p electrodes 714 arranged on p-side clad layers 713. A current is injected between p electrodes 714 and n electrode 716 provided on the back surface of substrate 710.

Semiconductor light emitting device 700 includes one or more resonators. In the present embodiment, semiconductor light emitting device 700 is a laser array which includes a plurality of resonators. In the regions of p-side clad layer 713 located on the sides of p electrode 714, a pair of grooves 721 are provided which extend parallel to the direction of resonance. In this way, in p-side clad layer 713 of semiconductor multilayer 709, a ridge for confining the light and the current can be formed.

In the present embodiment, semiconductor light emitting device 700 includes one or more groove regions 720 which are arranged above substrate 710 and which extend parallel to the direction of resonance. When semiconductor light emitting device 700 includes a plurality of p electrodes 714, between one p electrode 714 and other p electrodes 714, at least one groove region 720 deeper than groove 721 for forming the ridge is formed. In the present embodiment, groove region 720 reaches n-side clad layer 711 but does not reach substrate 710. The depth of groove region 720 is not particularly limited as long as the depth of groove region 720 reaches n-side clad layer 711 but does not reach substrate 710. For example, the depth of groove region 720 is 3 μm from the surface of semiconductor light emitting device 700. Although the width of groove region 720 is not particularly limited, the width is, for example, 100 μm.

When in semiconductor light emitting device 700 according to the present embodiment, the direction of tilt in a first plane included in n-side clad layer 711 and the direction of tilt in a second plane included in substrate 710 are assumed to be a direction which is tilted at 60 degrees or 120 degrees relative to the direction of resonance, as in embodiment 1, the relationship represented by formulae (1) and (2) or the relationship represented by formula (3) is established.

An example of the configuration of semiconductor light emitting device 700 according to the present embodiment is shown in table 7.

TABLE 7

| | | Composition, | Specific Configuration | Another Configuration |
|---|---|---|---|---|
| Sign | Name | Shape | Example | Example |
| 710 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 711 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 712 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 713 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 714 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 716 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 720 | Groove | Cross-sectional | Cross-sectional shape: | |
| | region | shape: tapered, | single-step shape | |
| | | multistep, etc. | Depth: 3 μm | |
| | | | (partway through n-side | |
| | | | clad layer) | |
| | | | Width: 100 μm | |

### Effects

Effects of semiconductor light emitting device 700 according to the present embodiment will then be described. Since in semiconductor light emitting device 700 according to the present embodiment, it is possible to reduce distortion, in a direction perpendicular to the direction of resonance, of n-side clad layer 711 sandwiched between two groove regions 720, the warpage of semiconductor light emitting device 700 in the direction perpendicular to the direction of resonance can be reduced while the volume of n-side clad layer 711 included in semiconductor light emitting device 700 is being increased.

Consequently, even when junction-down mounting is performed, the occurrence of a void in groove region 720 can be suppressed, and thus a laser chip in which the heat dissipation property and laser properties thereof are satisfactory can be realized.

Since in the present embodiment, n-side clad layer 711 is not separated by groove region 720, it is possible to suppress abnormal cleavage at ends where n-side clad layer 711 is separated when cleavage for forming the end surfaces of the resonators is performed. Hence, in the present embodiment, a highly reliable laser chip can be realized.

### Manufacturing Method

A method of manufacturing semiconductor light emitting device 700 according to the present embodiment is the same as the method of manufacturing semiconductor light emitting device 100 according to embodiment 1.

### Embodiment 8

A semiconductor light emitting device according to embodiment 8 will be described. The semiconductor light emitting device according to the present embodiment differs from semiconductor light emitting device 100 according to embodiment 1 in the shape of the groove region. The semiconductor light emitting device according to the present embodiment will be described below mainly on differences from semiconductor light emitting device 100 according to embodiment 1.

### Configuration

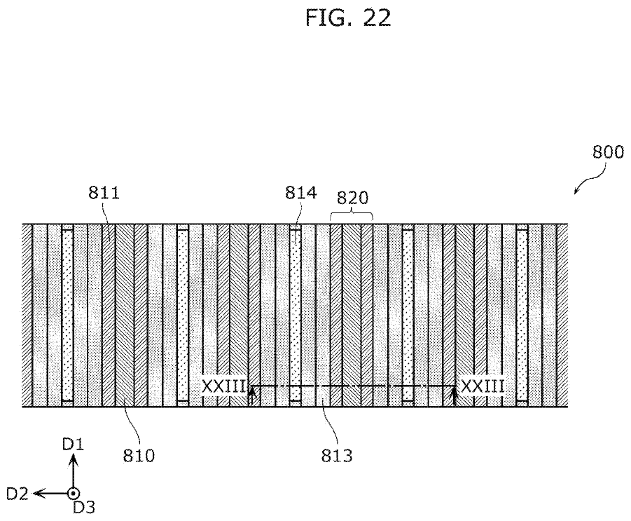

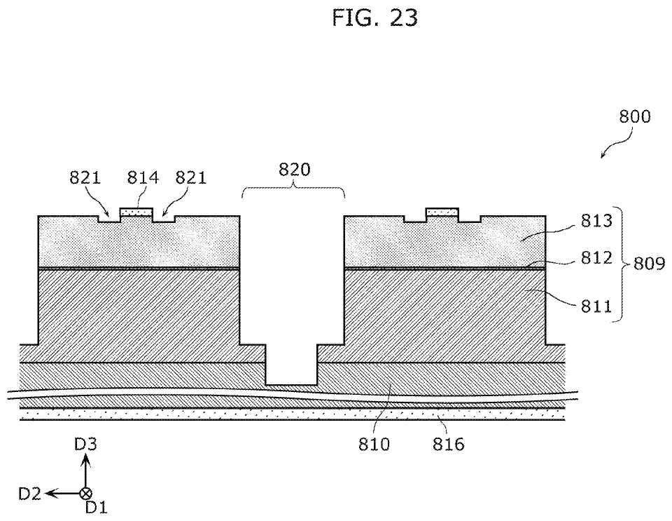

The configuration of the semiconductor light emitting device according to the present embodiment will first be described with reference to FIGS. 22 and 23. FIGS. 23 and 23 are respectively a schematic top view and a schematic cross-sectional view of semiconductor light emitting device 800 according to the present embodiment. FIG. 23 shows a cross section taken along line XXIII-XXIII in FIG. 23.

Semiconductor light emitting device 800 is a laser chip including a GaN-based material and the like, and includes, as shown in FIG. 23, substrate 810 and semiconductor multilayers 809 stacked on substrate 810. In the present embodiment, semiconductor light emitting device 800 further includes p electrodes 814 and n electrode 816. Although not shown in the figure, semiconductor light emitting device 800 further includes, as with semiconductor light emitting device 100 according to embodiment 1, a p-side pad electrode and a current block layer. Semiconductor multilayer 809 includes n-side clad layer 811 which is stacked above substrate 810, active layer 812 which is stacked above n-side clad layer 811, and p-side clad layer 813 which is stacked above active layer 812. In the present embodiment, semiconductor light emitting device 800 includes a plurality of p electrodes 814 arranged on p-side clad layers 813. A current is injected between p electrodes 814 and n electrode 816 provided on the back surface of substrate 810.

Semiconductor light emitting device 800 includes one or more resonators. In the present embodiment, semiconductor light emitting device 800 is a laser array which includes a plurality of resonators. In the regions of p-side clad layer 813 located on the sides of p electrode 814, a pair of grooves 821 are provided which extend parallel to the direction of resonance. In this way, in p-side clad layer 813 of semiconductor multilayer 809, a ridge for confining the light and the current can be formed.

In the present embodiment, semiconductor light emitting device 800 includes one or more groove regions 820 which are arranged above substrate 810 and which extend parallel to the direction of resonance. When semiconductor light emitting device 800 includes a plurality of semiconductor multilayers 809, between one semiconductor multilayer 809 and other semiconductor multilayers 809, at least one groove region 820 deeper than groove 821 for forming the ridge is formed.

In the present embodiment, groove region 820 has a two-step shape, that is, a staircase shape of two steps. As shown in FIG. 23, a groove in the first step of groove region 820 reaches n-side clad layer 811, and a groove in the second step reaches substrate 810.

Although the depth of the groove in the first step of groove region 820 is not particularly limited as long as the depth reaches n-side clad layer 811, the depth is, for example, 3 μm from the surface of semiconductor light emitting device 800. Although the width of the groove in the first step of groove region 820 is not particularly limited, the width is, for example, 100 μm.

Although the depth of the groove in the second step of groove region 820 is not particularly limited as long as the depth reaches substrate 810, the depth is, for example, 4 μm from the surface of semiconductor light emitting device 800. Although the width of the groove in the second step of groove region 820 is not particularly limited, the width is, for example, 2 μm.

Although in the present embodiment, groove region 820 has the two-step shape, groove region 820 may have a staircase shape of three or more steps, that is, a multistep shape of three or more steps.

When in semiconductor light emitting device 800 according to the present embodiment, the direction of tilt in a first plane included in n-side clad layer 811 and the direction of tilt in a second plane included in substrate 810 are assumed to be a direction which is tilted at 60 degrees or 120 degrees relative to the direction of resonance, as in embodiment 1, the relationship represented by formulae (1) and (2) or the relationship represented by formula (3) is established.

An example of the configuration of semiconductor light emitting device 800 according to the present embodiment is shown in table 8.

TABLE 8

| | | Composition, | Specific Configuration | Another Configuration |
|---|---|---|---|---|
| Sign | Name | Shape | Example | Example |
| 810 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 811 | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| 812 | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 813 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 814 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| — | P-side pad | Composition: | Composition: Ti/Au | |
| | electrode | Ti/Au, Ti/Pt/Au, | | |
| | | Ni/Au, etc. | | |
| 816 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| 820 | Groove | Cross-sectional | Cross-sectional shape: | |
| | region | shape: tapered, | two-step shape | |
| | | multistep, etc. | Depth: 4 μm | |
| | | | (First step depth: 2 μm) | |
| | | | (Second step depth: 2 μm) | |
| | | | Width: 100 μm | |

### Effects

Effects of semiconductor light emitting device 800 according to the present embodiment will then be described. Since in semiconductor light emitting device 800 according to the present embodiment, it is possible to reduce distortion, in a direction perpendicular to the direction of resonance, of n-side clad layer 811 sandwiched between two groove regions 820, the warpage of semiconductor light emitting device 800 in the direction perpendicular to the direction of resonance can be reduced while the volume of n-side clad layer 811 included in semiconductor light emitting device 800 is being increased.

Consequently, even when junction-down mounting is performed, the occurrence of a void in groove region 820 can be suppressed, and thus a laser chip in which the heat dissipation property and laser properties thereof are satisfactory can be realized.

In the present embodiment, groove region 820 has the two-step shape. Since groove region 820 in the present embodiment has a staircase shape as described above, as compared with the single-step groove region, the rate of coverage at the time of film formation of the current block layer and the p-side pad electrode is increased. Consequently, a leak through a step disconnection can be reduced, and thus a highly reliable laser chip can be realized.

### Manufacturing Method

A method of manufacturing semiconductor light emitting device 800 according to the present embodiment is the same as the method of manufacturing semiconductor light emitting device 100 according to embodiment 1.

### Embodiment 9

A semiconductor light emitting device according to embodiment 9 will be described. In the present embodiment, examples of the configurations of a p-side pad electrode and an n electrode in the semiconductor light emitting device will be described. The semiconductor light emitting device according to the present embodiment will be described below mainly on the configurations of the p-side pad electrode and the n electrode.

### Configuration

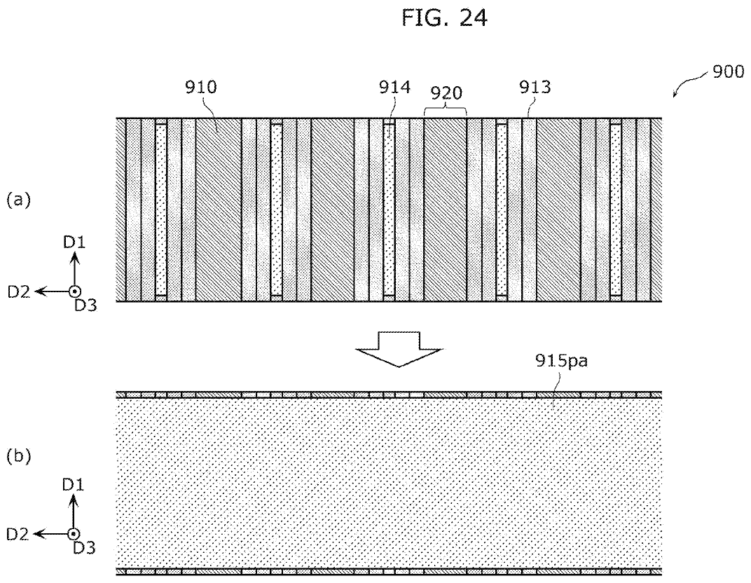

The configuration of the semiconductor light emitting device according to the present embodiment will first be described with reference to FIGS. 24 to 29. FIGS. 24 to 26 are schematic top views showing examples of the configuration of the p-side pad electrode in semiconductor light emitting device 900 according to the present embodiment. Top views (a) in FIGS. 24 to 26 show top views of semiconductor light emitting device 900 before the p-side pad electrode is formed. Top views (b) in FIGS. 24 to 26 show top views of semiconductor light emitting device 900 after the p-side pad electrode is formed.

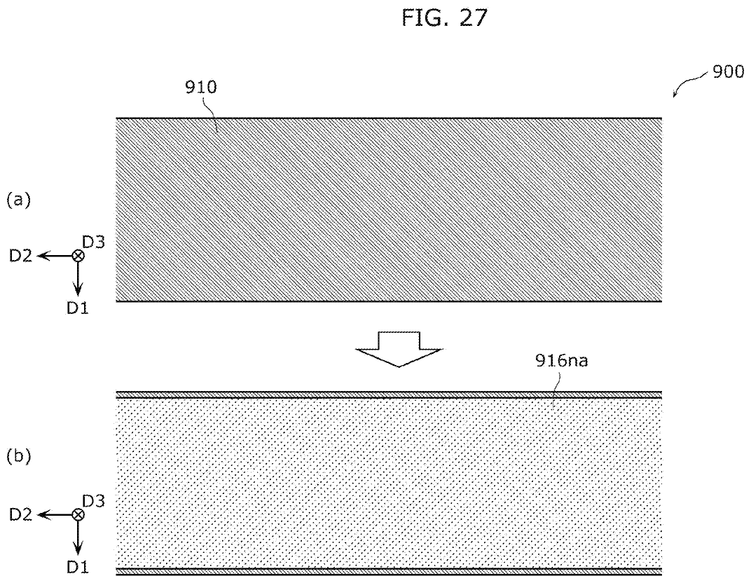

FIGS. 27 to 29 are schematic bottom views showing examples of the configuration of the n-side electrode in semiconductor light emitting device 900 according to the present embodiment. Bottom views (a) in FIGS. 27 to 29 show bottom views of semiconductor light emitting device 900 before the n electrode is formed. Bottom views (b) in FIGS. 27 to 29 show bottom views of semiconductor light emitting device 900 after the n electrode is formed.

Semiconductor light emitting device 900 according to the present embodiment is a laser chip including a GaN-based material, and includes substrate 910 and semiconductor multilayers. Substrate 910 and the semiconductor multilayer in the present embodiment respectively have the same configurations as substrate 110 and semiconductor multilayer 109 in embodiment 1. Semiconductor light emitting device 900 includes p electrodes 914, the p-side pad electrode, and the n electrode. Although not shown in the figure, semiconductor light emitting device 900 further includes a current block layer as with semiconductor light emitting device 100 according to embodiment 1.

The semiconductor multilayer in the present embodiment includes an n-side clad layer (not shown in FIGS. 24 to 29) which is stacked above substrate 910, an active layer (not shown in FIGS. 24 to 29) which is stacked above the n-side clad layer, and p-side clad layer 913 which is stacked above the active layer.

Semiconductor light emitting device 900 according to the present embodiment includes one or more groove regions 920 which are arranged above substrate 910 and which extend parallel to the direction of resonance. Groove region 920 has the same configuration as groove region 120 in embodiment 1.

In semiconductor light emitting device 900 as described above, for example, the configurations of the p-side pad electrode as shown in FIGS. 24 to 26 can be applied.

One p-side pad electrode 915pa as shown in FIG. 24 which covers a substantially entire top surface of substrate 910 may be applied to semiconductor light emitting device 900. As shown in FIG. 24, p-side pad electrode 915pa covers substantially entire top surfaces of the semiconductor multilayers including the tops of p electrodes 914 and substantially entire surfaces of groove regions 920. In other words, p-side pad electrode 915pa is continuously formed on all resonators and groove regions 920. P-side pad electrode 915pa is an integral electrode which supplies a current to all the resonators.

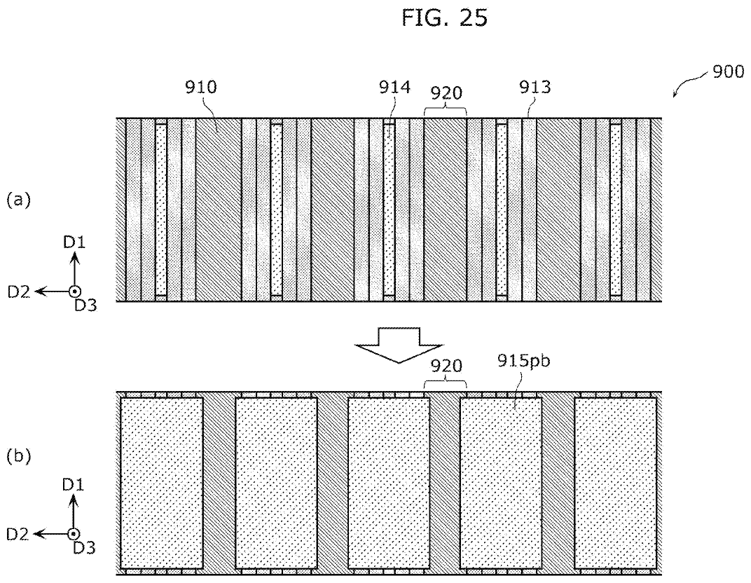

P-side pad electrodes 915pb as shown in FIG. 25 which are arranged on the top surfaces of the resonators and which are equal in number to the resonators may be applied to semiconductor light emitting device 900.

For example, p-side pad electrodes 915pb equal in number to the resonators are separated from each other by groove regions 920. For example, when semiconductor light emitting device 900 includes 38 resonators, semiconductor light emitting device 900 may include 38 p-side pad electrodes 915pb.

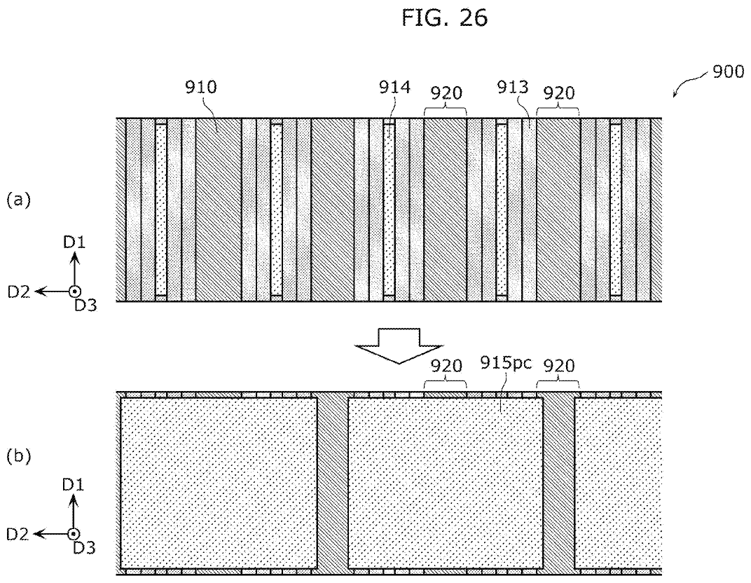

A plurality of p-side pad electrodes 915pc as shown in FIG. 26 may be applied to semiconductor light emitting device 900. Each of p-side pad electrodes 915pc shown in FIG. 26 collectively covers the top surfaces of a plurality of resonators. The p-side pad electrodes 915pc are separated from each other by groove regions 920. For example, each of p-side pad electrodes 915pc may collectively cover two resonators. For example, when semiconductor light emitting device 900 includes 38 resonators, semiconductor light emitting device 900 may include 19 p-side pad electrodes 915pb.

In semiconductor light emitting device 900 according to the present embodiment, the configurations of various p-side pad electrodes as described above can be applied.

In semiconductor light emitting device 900, for example, the configurations of n electrodes as shown in FIGS. 27 to 29 can be applied.

One n electrode 916na shown in FIG. 27 which covers a substantially entire bottom surface of substrate 910 may be applied to semiconductor light emitting device 900. N electrode 916na is an integral electrode which supplies a current to a plurality of resonators.

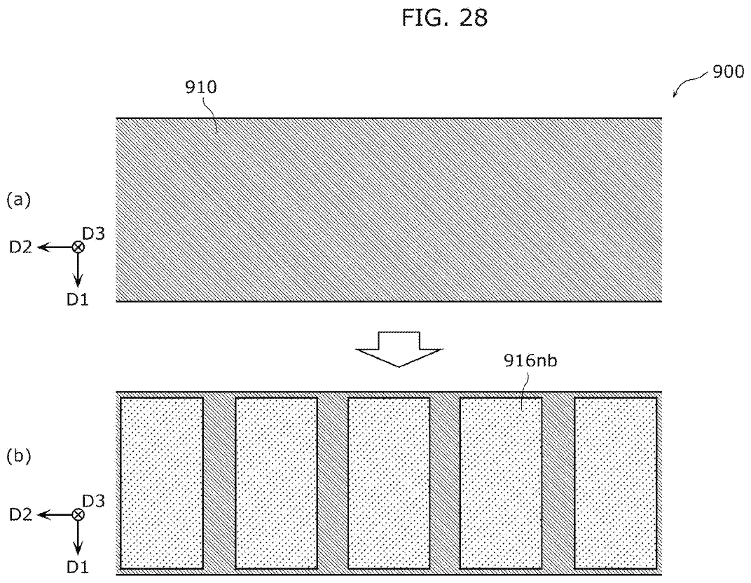

N electrodes 916nb as shown in FIG. 28 which are arranged in positions corresponding to the resonators and which are equal in number to the resonators may be applied to semiconductor light emitting device 900. N electrodes 916nb equal in number to the resonators are separated from each other by regions of substrate 910 opposite the bottom of groove regions 920. For example, when semiconductor light emitting device 900 includes 38 resonators, semiconductor light emitting device 900 may include 38 n electrodes 916nb.

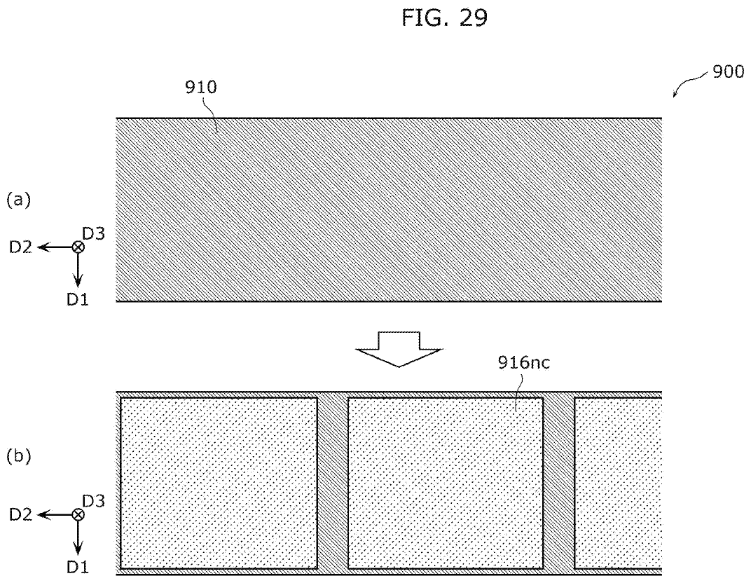

A plurality of n electrodes 916nc as shown in FIG. 29 may be applied to semiconductor light emitting device 900. Each of n electrodes 916nc shown in FIG. 29 collectively covers the bottom surfaces of a plurality of resonators. N electrodes 916nc are separated from each other by regions of substrate 910 opposite the bottom of groove regions 920. Each of n electrodes 916nc may collectively cover two resonators. For example, when semiconductor light emitting device 900 includes 38 resonators, semiconductor light emitting device 900 may include 19 n electrodes 916nb.

An example of the configuration of semiconductor light emitting device 900 according to the present embodiment is shown in table 9.

TABLE 9

| | | Composition, | Specific Configuration | Another Configuration |
|---|---|---|---|---|
| Sign | Name | Shape | Example | Example |
| 910 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| — | N-side clad | Composition: | Composition: Al_{0.03}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 3 μm | |
| | | or more | | |
| — | Active layer | Composition: | Composition: | |
| | | InₓGaN (0 < x < 1)/ | In_{0.06}GaN/GaN | |
| | | AlₓIn_{y}GaN | (quantum well structure) | |
| | | (x, y ≥ 0) | Thickness: 5 nm/10 nm | |
| | | (quantum well | Number of wells: 2 | |
| | | structure) | | |
| 913 | P-side clad | Composition: | Composition: AlGaN/GaN | |
| | layer | AlₓGaN (0 < x < 1) | superlattice | |
| | | Dopant: Mg | Average Al composition | |
| | | Thickness: 0.1 μm | ratio: 3% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 914 | P electrode | Composition: at | Composition: Pd/Pt | Multilayer film can be |
| | | least one of Cr, Ti, | Width: 16 μm | used. |
| | | Ni, Pd, Pt, and Au | Interval: 225 μm | |
| | | Width: 10 μm or | | |
| | | more, 150 μm or | | |
| | | less | | |
| 915pa | P-side pad | Composition: | Composition: Ti/Au | |
| | electrode | Ti/Au, Ti/Pt/Au, | Size: 9.95 mm × 1.98 mm | |
| | | Ni/Au, etc. | | |
| 915pb | P-side pad | Composition: | Composition: Ti/Au | |
| | electrode | Ti/Au, Ti/Pt/Au, | Size: 0.2 mm × 1.98 mm | |
| | | Ni/Au, etc. | Number of electrodes: 38 | |
| 915pc | P-side pad | Composition: | Composition: Ti/Au | |
| | electrode | Ti/Au, Ti/Pt/Au, | Size: 0.4 mm × 1.98 mm | |
| | | Ni/Au, etc. | Number of electrodes: 19 | |
| 916na | N electrode | Composition: | Composition: Ti/Pt/Au | |
| | | Ti/Au, Ti/Pt/Au, | Size: 9.95 mm × 1.98 mm | |
| | | etc. | | |
| 916nb | N electrode | Composition: | Composition: Ti/Pt/Au | |
| | | Ti/Au, Ti/Pt/Au, | Size: 0.2 mm × 1.98 mm | |
| | | etc. | Number of electrodes: 38 | |
| 916nc | N electrode | Composition: | Composition: Ti/Pt/Au | |
| | | Ti/Au, Ti/Pt/Au, | Size: 0.4 mm × 1.98 mm | |
| | | etc. | Number of electrodes: 19 | |
| — | Current | Composition: | Composition: SiO₂ | |
| | block layer | SiO₂, SiN | Thickness: 200 nm | |
| | | Thickness: 100 | | |
| | | nm or more, 500 | | |
| | | nm or less | | |
| — | Groove | Cross-sectional | Cross-sectional shape: | |
| | region | shape: tapered, | single-step shape | |
| | | multistep, etc. | Depth: 4 μm | |
| | | | Width: 100 μm | |

### Effects

Effects of semiconductor light emitting device 900 according to the present embodiment will then be described. Since in semiconductor light emitting device 900 according to the present embodiment, it is possible to reduce distortion, in a direction perpendicular to the direction of resonance, of the n-side clad layer sandwiched between two groove regions 920, the warpage of semiconductor light emitting device 900 in the direction perpendicular to the direction of resonance can be reduced while the volume of the n-side clad layer included in semiconductor light emitting device 900 is being increased.

Consequently, even when junction-down mounting is performed, the occurrence of a void in groove region 820 can be suppressed, and thus a laser chip in which the heat dissipation property and laser properties thereof are satisfactory can be realized.

In the present embodiment, a difference in thermal coefficient of expansion between the p-side pad electrode and the n electrode and substrate 910 is utilized, and thus it is possible to more accurately control the warpage.

When a plurality of semiconductor light emitting devices are manufactured on one wafer, the layout of the electrodes is changed inside a wafer surface, and thus it is possible to reduce variations in the equality of the substrate and the semiconductor multilayer.

### Manufacturing Method

Although a method of manufacturing semiconductor light emitting device 900 according to the present embodiment is the same as the method of manufacturing semiconductor light emitting device 100 according to embodiment 1, temperature control may be performed at the time of film formation of the p-side pad electrode and the n electrode to more accurately control the warpage.

### Embodiment 10

A semiconductor light emitting device according to embodiment 10 will be described. The semiconductor light emitting device according to the present embodiment differs from semiconductor light emitting device 100 according to embodiment 1 in that the semiconductor light emitting device is not a laser chip but a light emitting diode (LED). The semiconductor light emitting device according to the present embodiment will be described below mainly on differences from semiconductor light emitting device 100 according to embodiment 1.

### Configuration

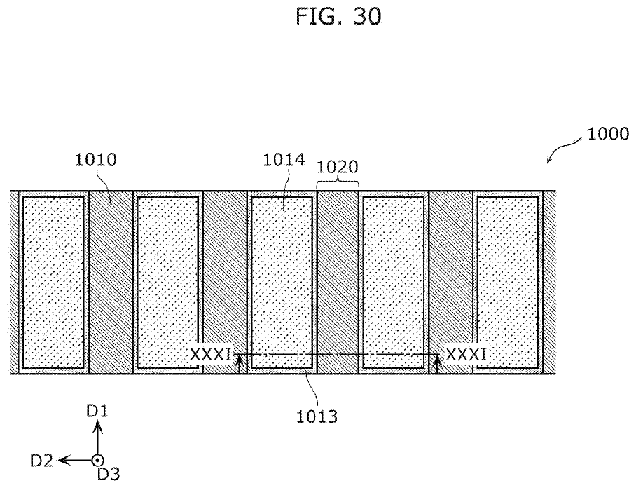

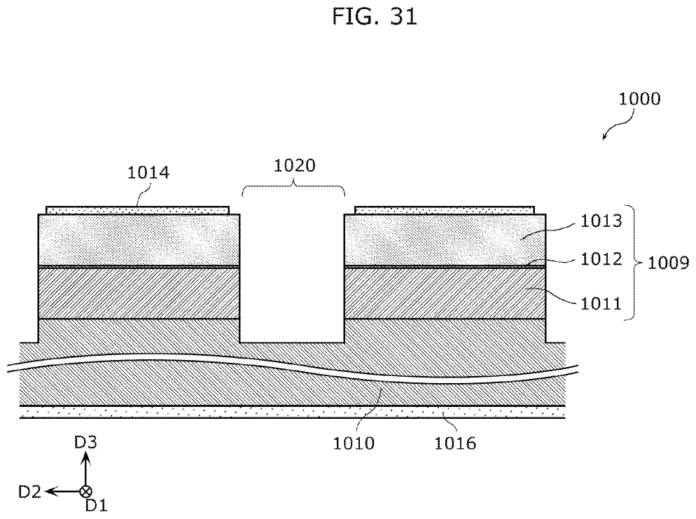

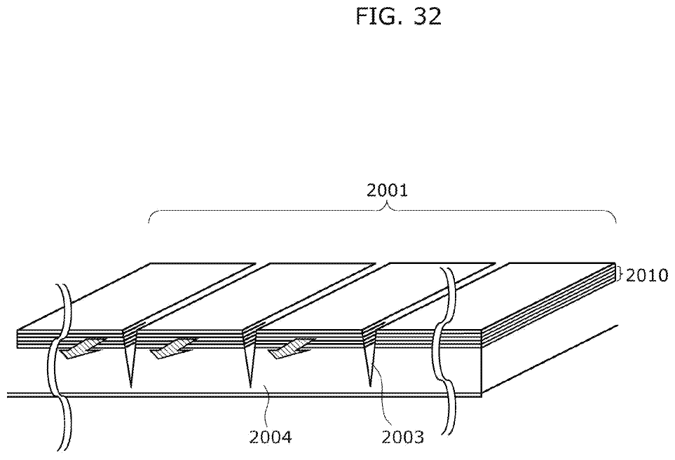

The configuration of the semiconductor light emitting device according to the present embodiment will first be described with reference to FIGS. 30 and 31. FIGS. 30 and 31 are respectively a schematic top view and a schematic cross-sectional view of semiconductor light emitting device 1000 according to the present embodiment. FIG. 31 shows a cross section taken along line XXXI-XXXI in FIG. 30.

Semiconductor light emitting device 1000 is a light emitting element including a GaN-based material and the like, and includes, as shown in FIG. 31, substrate 1010 and semiconductor multilayers 1009 stacked on substrate 1010. In the present embodiment, semiconductor light emitting device 1000 further includes p electrodes 1014 and n electrode 1016. Although not shown in the figure, semiconductor light emitting device 1000 further includes, as with semiconductor light emitting device 100 according to embodiment 1, a p-side pad electrode and a current block layer. Semiconductor multilayer 1009 includes n-side clad layer 1011 which is stacked above substrate 1010, active layer 1012 which is stacked above n-side clad layer 1011, and p-side clad layer 1013 which is stacked above active layer 1012. In the present embodiment, semiconductor multilayer 1009 includes a gallium nitride-based semiconductor. Semiconductor light emitting device 1000 includes a plurality of p electrodes 1014 arranged on p-side clad layers 1013. In the present embodiment, each of p electrodes 1014 is a transparent electrode including a transparent conductive film. On part of the top of p electrode 1014, a wiring electrode (not shown) is provided. A current is injected between p electrodes 1014 and n electrode 1016 provided on the back surface of substrate 1010.

Active layer 1012 includes AlₓIn_{y}GaN (0≤x,y). In this way, active layer 1012 has a large band gap due to GaN. The band gap of active layer 1012 is smaller than the band gaps of n-side clad layer 1011 and p-side clad layer 1013.

Semiconductor light emitting device 100 includes one or more groove regions 1020 arranged above substrate 1010. In the present embodiment, as shown in FIG. 30, semiconductor light emitting device 1000 includes a plurality of groove regions 1020. As shown in FIG. 31, each of groove regions 1020 may reach substrate 1010. In this way, it is possible to reduce distortion resulting from a lattice mismatch between substrate 1010 and semiconductor multilayer 1009.

Here, the crystal structure of n-side clad layer 1011 in the present embodiment will be described.

Semiconductor multilayer 1009 includes a first plane perpendicular to a stacking direction in which semiconductor multilayer 1009 is stacked. The first plane includes, inside the plane, a first orientation and a third orientation which is tilted relative to the first orientation. In the present embodiment, an orientation which is tilted at 60 degrees or 120 degrees relative to the first orientation inside the first plane is assumed to be the third orientation. In the present embodiment, n-side clad layer 1011 of semiconductor multilayer 1009 includes the first plane.

On the other hand, substrate 1010 includes a second plane perpendicular to the stacking direction. The second plane includes, inside the plane, a second orientation parallel to the first orientation and a fourth orientation which is tilted relative to the second orientation and which is parallel to the third orientation. In the present embodiment, an orientation which is tilted at 60 degrees or 120 degrees relative to the second orientation inside the second plane is assumed to be the fourth orientation.

First lattice constant dcm of n-side clad layer 1011 in the first orientation is equal to second lattice constant dsm of substrate 1010 in the second orientation. Here, a state where first lattice constant dcm is equal to second lattice constant dsm is not limited to a state where first lattice constant dcm is completely identical to second lattice constant dsm, and includes a state where they are substantially the same. For example, a state where a difference between lattice constant dsm and lattice constant dcm is less than or equal to 0.01% of lattice constant dsm or lattice constant dcm is also included in the state where lattice constant dsm is equal to lattice constant dcm.

Third lattice constant dca of n-side clad layer 1011 in the third orientation is less than fourth lattice constant dsa of substrate 1010 in the fourth orientation.

In other words, for the lattice constants described above, a relationship represented by formulae (4) and (5) below is established.

dsm≈dcm (4)

dsa>dca (5)

Instead of the relationship represented by formulae (4) and (5) above, a relationship represented by formula (6) below may be established.

dsm-dcm<dsa-dca (6)

Semiconductor multilayer 1009 is, for example, a GaN-based semiconductor. The first orientation is preferably any one of [1-100] orientation, [0-110] orientation, and [−1010] orientation. Preferably, the third orientation is any one of [1-100] orientation, [0-110] orientation, and [−1010] orientation and is one of two orientations having Miller indices different from the first orientation.

An example of the configuration of the semiconductor light emitting device according to the present embodiment is shown in table 10.

TABLE 10

| | | Composition, | Specific Configuration | Another Configuration |
|---|---|---|---|---|
| Sign | Name | Shape | Example | Example |
| 1010 | Substrate | Composition: | Composition etc.: GaN | Crystal system having |
| | | GaN, SiC, | single crystal substrate | lattice mismatch for n- |
| | | sapphire | oriented to c-axis | side clad layer can be |
| | | | Size: 10 mm × 2 mm | used instead. |
| 1011 | N-side clad | Composition: | Composition: Al_{0.10}GaN | |
| | layer | AlₓGaN (0 < x < 1) | Si concentration: 1 × 10¹⁷ | |
| | | Dopant: Si | cm⁻³ | |
| | | Thickness: 1 μm | Thickness: 1 μm | |
| | | or more | | |
| 1012 | Active layer | Composition: | Composition: Al_{0.06}GaN/ | |
| | | AlₓIn_{y}GaN | Al_{0.10}GaN | |
| | | (x, y ≥ 0)/ | (quantum well structure) | |
| | | AlₓIn_{y}GaN | Thickness: 5 nm/10 nm | |
| | | (x, y ≥ 0) | Number of wells: 2 | |
| | | (quantum well | | |
| | | structure) | | |
| 1013 | P-side clad | Composition: | Composition: AlGaN/GaN | |
| | layer | AlₓGaN (0 < x < 1) | superlattice | |
| | | Dopant: Si | Average Al composition | |
| | | Thickness: 0.1 μm | ratio: 10% | |
| | | or more, 1 μm or | Mg concentration: 1 × 10¹⁹ | |
| | | less | cm⁻³ | |
| | | | Thickness: 3 nm/3 nm | |
| | | | Number of superlattice | |
| | | | layers: 100 SLs | |
| 1014 | P electrode | Composition: ITO | Composition: ITO | Multilayer film can be |
| | | etc. | Width: 170 μm | used. |
| | | (transparent | Interval: 225 μm | |
| | | conductive film) | | |
| — | Wiring | Composition: | Composition: Ti/Au | |
| | electrode | Ti/Au, Ti/Pt/Au, | | |
| | | Ni/Au, etc. | | |
| 1016 | N electrode | Composition: | Composition: Ti/Pt/Au | |
| | | Ti/Au, Ti/Pt/Au, | | |
| | | etc. | | |
| — | Current | Composition: | Composition: SiO₂ | |
| | block layer | SiO₂, SiN | Thickness: 200 nm | |
| | | Thickness: 10 nm | | |
| | | or more, 500 nm | | |
| | | or less | | |
| 1020 | Groove | Cross-sectional | Cross-sectional shape: | |
| | region | shape: tapered, | single-step shape | |
| | | multistep, etc. | Depth: 4 μm | |
| | | | Width: 50 μm | |

### Effects

Effects of semiconductor light emitting device 1000 according to the present embodiment will then be described.

Active layer 1012 in the present embodiment has a lattice mismatch for substrate 1010 as with active layer 412 in embodiment 4, and thus active layer 1012 is in a state where tensile distortion is applied thereto. Therefore, an electric field caused by the distortion is generated inside active layer 1012. Consequently, the gradient of an energy band structure is steep, and thus electrons and holes are spatially isolated. Hence, the overlap integral of the wave function of electrons and holes is decreased, and thus recombination efficiency is lowered. The efficiency of light emission of the semiconductor light emitting device is lowered accordingly.

In the present embodiment, groove region 1020 is formed, and thus as described above, the lattice constant of n-side clad layer 1011 in the third orientation perpendicular to the stacking direction is decreased, with the result that the tensile distortion applied to active layer 1012 is decreased. Hence, the electric field caused by the internal distortion is reduced. Consequently, the overlap integral of the wave function of electrons and holes is increased, and thus recombination efficiency is increased. Therefore, the efficiency of light emission of semiconductor light emitting device 1000 is enhanced.

### Manufacturing Method

A method of manufacturing semiconductor light emitting device 1000 according to the present embodiment is the same as the method of manufacturing semiconductor light emitting device 100 according to embodiment 1 except that the groove for forming the ridge is not formed and that p electrode 1014 includes the transparent conductive film.

### Variations and the Like

Although the semiconductor light emitting device according to the present disclosure has been described above based on the embodiments, the present disclosure is not limited to the embodiments described above.

Embodiments obtained by performing various variations conceived by a person skilled in the art on the embodiments described above and embodiments realized by arbitrarily combining the constituent elements and the functions in the embodiments described above without departing from the spirit of the present disclosure are also included in the present disclosure.

For example, the p-side pad electrode and the n electrode in embodiment 9 may be applied to the semiconductor light emitting devices according to the other embodiments.

Although in the embodiments described above, as the semiconductor light emitting device, the examples of the laser chip and the LED are described, the semiconductor light emitting device according to the present disclosure is not limited to these examples. For example, the semiconductor light emitting device may be a super luminescent diode.

Although in the embodiments described above, the semiconductor multilayer includes the n-side clad layer, the active layer, and the p-side clad layer, a layer other than those may be inserted. For example, a buffer layer may be inserted between the substrate and the n-side clad layer or a light guide layer adjacent to the active layer may be inserted.

### INDUSTRIAL APPLICABILITY

For example, the semiconductor light emitting device according to the present disclosure can be applied as a high-power and high-efficient light source to a processing device, an illumination device and the like.

1. A semiconductor light emitting device that emits light in a direction of resonance, the semiconductor light emitting device comprising:
a substrate; and
one or more semiconductor multilayers stacked on the substrate,
wherein each of the one or more semiconductor multilayers includes:
an n-side clad layer stacked above the substrate;
an active layer stacked above the n-side clad layer; and
a p-side clad layer stacked above the active layer,
each of the one or more semiconductor multilayers includes a first plane perpendicular to a stacking direction in which the one or more semiconductor multilayers are stacked, and
a lattice constant inside the first plane is an anisotropy constant.

2. The semiconductor light emitting device according to claim 1,
wherein the substrate includes a second plane perpendicular to the stacking direction,
a lattice constant inside the first plane in the direction of resonance is equal to a lattice constant inside the second plane in the direction of resonance, and
a lattice constant inside the first plane in a direction of tilt that is tilted relative to the direction of resonance is less than a lattice constant inside the second plane in the direction of tilt.

3. The semiconductor light emitting device according to claim 1 comprising:
one or more groove regions that are arranged above the substrate to extend parallel to the direction of resonance.

4. The semiconductor light emitting device according to claim 1,
wherein a dislocation that occurs in an interface between the substrate and the one or more semiconductor multilayers is less than or equal to 10⁷ cm⁻².

5. The semiconductor light emitting device according to claim 1,
wherein the active layer includes a gallium nitride-based material.

6. The semiconductor light emitting device according to claim 5,
wherein the substrate includes GaN, and
a major surface of the substrate is a c-plane.

7. The semiconductor light emitting device according to claim 1,
wherein the one or more semiconductor multilayers include a plurality of semiconductor multilayers, and
a width of each of the one or more semiconductor multilayers in the direction of resonance is less than a total of widths in a direction perpendicular to the direction of resonance and the stacking direction.

8. The semiconductor light emitting device according to claim 3,
wherein the one or more semiconductor multilayers include a plurality of semiconductor multilayers, and
a number obtained by subtracting 1 from a total number of the one or more semiconductor multilayers is greater than a total number of the groove regions.

9. The semiconductor light emitting device according to claim 3,
wherein a total number of the one or more semiconductor multilayers is less than a total number of the groove regions.

10. The semiconductor light emitting device according to claim 1,
wherein the active layer includes at least Al.

11. A semiconductor light emitting device comprising:
a substrate; and
one or more semiconductor multilayers stacked on the substrate,
wherein each of the one or more semiconductor multilayers includes:
an n-side clad layer stacked above the substrate;
an active layer that is stacked above the n-side clad layer and includes at least Al; and
a p-side clad layer stacked above the active layer,
each of the one or more semiconductor multilayers includes a first plane perpendicular to a stacking direction in which the one or more semiconductor multilayers are stacked,
the first plane includes, inside the first plane, a first orientation and a third orientation that is tilted relative to the first orientation,
the substrate includes a second plane perpendicular to the stacking direction,
the second plane includes, inside the second plane, a second orientation parallel to the first orientation and a fourth orientation that is tilted relative to the second orientation and is parallel to the third orientation,
a first lattice constant in the first orientation is equal to a second lattice constant in the second orientation, and
a third lattice constant in the third orientation is less than a fourth lattice constant in the fourth orientation.

12. The semiconductor light emitting device according to claim 11,
wherein the one or more semiconductor multilayers includes a gallium nitride-based semiconductor,
the first orientation is any one of [1-100] orientation, [0-110] orientation, and [−1010] orientation, and
the third orientation is any one of [1-100] orientation, [0-110] orientation, and [−1010] orientation and is one of two orientations having Miller indices different from the first orientation.

13. The semiconductor light emitting device according to claim 11,
wherein the third orientation is tilted at 60 degrees or 120 degrees relative to the first orientation, and
the fourth orientation is tilted at 60 degrees or 120 degrees relative to the second orientation.
